(19) United States
(12) Patent Application Publication
(10) Pub. No.: US 2026/0182057 A1
(43) Pub. Date: Jun. 25, 2026

(54) IMAGE SENSOR HAVING AIR GAP

(71) Applicant: Samsung Electronics Co., Ltd., Suwon-si (KR)

(72) Inventors: BYUNGHONG CHUNG, Suwon-si (KR); SEOKJIN KWON, Suwon-si (KR); SUNG IN KIM, Suwon-si (KR); Jinhyung Kim, Suwon-si (KR); CHANGROK MOON, Suwon-si (KR); Sunwook Park, Suwon-si (KR); INYONG PARK, Suwon-si (KR); Yangjae Yun, Suwon-si (KR); BEOMSUK LEE, Suwon-si (KR); IN SUNG JOE, Suwon-si (KR)

(21) Appl. No.: 19/430,815

(22) Filed: Dec. 23, 2025

(30) Foreign Application Priority Data
Dec. 24, 2024 (KR) 10-2024-0195521

(51) Int. Cl. H10F 39/00

(52) U.S. Cl. CPC H10F 39/8053; H10F 39/806; H10F 39/8063; H10F 39/807

(57) ABSTRACT

An image sensor includes a substrate having a first surface and a second surface opposing the first surface, a transmissive insulating layer provided on the second surface of the substrate, a plurality of color filters provided on the transmissive insulating layer, a plurality of planarization patterns provided on the plurality of color filters, a first air gap provided within a recess between the plurality of color filters and between the plurality of planarization patterns, and a first glass substrate provided on the plurality of planarization patterns and the first air gap and closing an upper end of the first air gap.

### CROSS-REFERENCE TO RELATED APPLICATION(S)

This U.S. non-provisional application claims priority under 35 USC § 119 to Korean Patent Application No. 10-2024-0195521, filed on Dec. 24, 2024, in the Korean Intellectual Property Office, the disclosure of which is herein incorporated by reference in its entirety.

### BACKGROUND

The present disclosure relates to an image sensor having an air gap.

An image sensor is a semiconductor device converting an optical image into an electrical signal. With the recent advancement of the computer and telecommunications industries, the demand for high-performance image sensors has been increasing across various applications including digital cameras, camcorders, personal communication systems (PCS), gaming devices, security cameras, and medical micro-cameras. Image sensors may be classified into two main types: charge coupled device (CCD) type and complementary metal-oxide-semiconductor (CMOS) type. A CMOS image sensor includes a plurality of pixels arranged in a two-dimensional array. Each of the pixels includes a photodiode (PD). The photodiode serves to convert incident light into an electrical signal.

### SUMMARY

One or more embodiments provide an image sensor with reduced crosstalk.

One or more embodiments provide an image sensor with improved photoelectric conversion efficiency by significantly reducing optical loss.

According to an aspect of the present disclosure, an image sensor includes a substrate having a first surface and a second surface opposing the first surface, a transmissive insulating layer provided on the second surface of the substrate, a plurality of color filters provided on the transmissive insulating layer, a plurality of planarization patterns provided on the plurality of color filters, a first air gap provided within a recess between the plurality of color filters and between the plurality of planarization patterns, and a first glass substrate provided on the plurality of planarization patterns and the first air gap and closing an upper end of the first air gap.

According to an aspect of the present disclosure, an image sensor includes a substrate having a first surface and a second surface opposing the first surface, a transmissive insulating layer provided on the second surface of the substrate, a plurality of color filters provided on the transmissive insulating layer and comprising a first color filter and a second color filter having different heights relative to the second surface of the substrate, a plurality of planarization patterns provided on the plurality of color filters, a first air gap provided within a recess between the plurality of color filters and between the plurality of planarization patterns, a first glass substrate provided on the plurality of planarization patterns and the first air gap to close an upper end of the first air gap, a first isolation pattern provided in the substrate to define a plurality of pixel regions and comprising a second air gap, and a second glass substrate provided between the substrate and the transmissive insulating layer to close an upper end of the second air gap. The first color filter and the second color filter are configured to transmit light of different wavelengths.

According to an aspect of the present disclosure, an image sensor includes a substrate having a first surface and a second surface opposing the first surface, a transmissive insulating layer provided on the second surface of the substrate, a plurality of color filters provided on the transmissive insulating layer and comprising a first color filter and a second color filter having different heights relative to the second surface of the substrate, a plurality of planarization patterns provided on the plurality of color filters, a first air gap provided within a recess between the plurality of color filters and between the plurality of planarization patterns, a first glass substrate provided on the plurality of planarization patterns and the first air gap to close an upper end of the first air gap, a first isolation pattern provided in the substrate to define a plurality of pixel regions and comprising a second air gap, a second glass substrate provided between the substrate and the transmissive insulating layer to close an upper end of the second air gap, and a plurality of meta-microlenses covering the plurality of pixel regions and each comprising a first nanostructure layer on the first glass substrate and a second nanostructure layer on the first nanostructure layer. The first color filter and the second color filter are configured to transmit light of different wavelengths. Each of the plurality of meta-microlenses comprises a third glass substrate provided between the first nanostructure layer and the second nanostructure layer.

### BRIEF DESCRIPTION OF DRAWINGS

FIG. 1 is a block diagram of an image sensor according to one or more embodiments.

FIG. 2 is a circuit diagram of pixels included in a pixel array of an image sensor according to one or more embodiments.

FIG. 3A is a plan view of a grid recess and pixel regions according to one or more embodiments.

FIG. 3B is a cross-sectional view taken along line A-A′ of FIG. 3A.

FIG. 4 is a cross-sectional view of an image sensor according to one or more embodiments.

FIG. 5 is a cross-sectional view of an image sensor according to one or more embodiments.

FIG. 6 is a cross-sectional view of an image sensor according to one or more embodiments.

FIG. 7 is a cross-sectional view of an image sensor according to one or more embodiments.

FIG. 8 is a cross-sectional view of an image sensor according to one or more embodiments.

FIG. 9 is a cross-sectional view of an image sensor according to one or more embodiments.

FIG. 10 is a cross-sectional view of an image sensor according to one or more embodiments.

FIG. 11 is a cross-sectional view of an image sensor according to one or more embodiments.

FIG. 12 is a cross-sectional view of an image sensor according to one or more embodiments.

FIG. 13 is a cross-sectional view of an image sensor according to one or more embodiments.

FIG. 14 is a cross-sectional view of an image sensor according to one or more embodiments.

FIG. 15 is a cross-sectional view of an image sensor according to one or more embodiments.

FIGS. 16A to 16I are cross-sectional views illustrating a method of manufacturing an image sensor according to one or more embodiments.

FIGS. 17A to 17D are cross-sectional views illustrating a method of manufacturing an image sensor according to one or more embodiments.

FIGS. 18A to 18D are cross-sectional views illustrating a method of manufacturing an image sensor according to one or more embodiments.

FIG. 19 is a cross-sectional view illustrating a method of manufacturing an image sensor according to one or more embodiments.

FIGS. 20A to 20C are cross-sectional views illustrating a method of manufacturing an image sensor according to one or more embodiments.

FIGS. 21A and 21B are cross-sectional views illustrating a method of manufacturing an image sensor according to one or more embodiments.

FIGS. 22A and 22B are cross-sectional views illustrating a method of manufacturing an image sensor according to one or more embodiments.

### DETAILED DESCRIPTION

Hereinafter, example embodiments will be described with reference to the accompanying drawings.

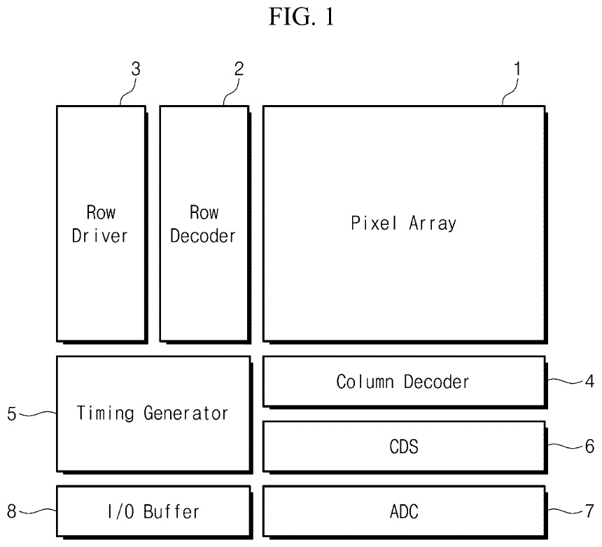

FIG. 1 is a block diagram of an image sensor according to one or more embodiments.

Referring to FIG. 1, an image sensor according to one or more embodiments may include a pixel array 1, a row decoder 2, a row driver 3, a column decoder 4, a timing generator 5, a correlated double sampler 6, an analog-to-digital converter 7, and an input/output buffer 8.

The pixel array 1 may include a plurality of pixels arranged two-dimensionally, and the pixels can convert optical signals into electrical signals. The pixel array 1 may be driven by a plurality of driving signals (for example, pixel selection signal, reset signal, and/or charge transfer signal) transmitted from the row driver 3. The converted electrical signals may be provided to the correlated double sampler 6.

The row driver 3 may provide a plurality of driving signals to the pixel array 1 to drive the plurality of pixels based on a decoding result from the row decoder 2. When the pixels are arranged in a matrix, the driving signals may be provided in units of rows.

The timing generator 5 may provide timing signals and control signals to the row decoder 2 and the column decoder 4.

The correlated double sampler 6 may receive electrical signals generated by the pixel array 1, and hold and sample the received signals. The correlated double sampler 6 may perform double sampling on a specific noise level and a signal level caused by an electrical signal to output a difference level corresponding to a difference between the noise level and the signal level.

The analog-to-digital converter 7 may convert an analog signal corresponding to the difference level, output from the correlated double sampler 6, into a digital signal and output the digital signal.

The input/output buffer 8 may latch the digital signals and sequentially output the latched signals to an image signal processor, not illustrated, based on a decoding result from the column decoder 4.

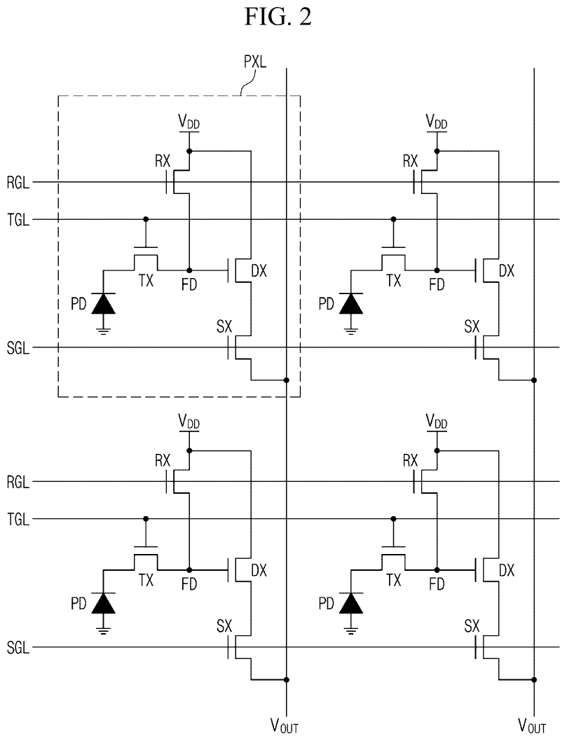

FIG. 2 is a circuit diagram of pixels included in a pixel array of an image sensor according to one or more embodiments.

Referring to FIG. 2, the pixel array may include a plurality of pixels PXL, and the pixels PXL may be arranged in a matrix. Each of the pixels PXL may include pixel transistors, and the pixel transistors may include a transfer transistor TX and logic transistors RX, SX, and SFX. The logic transistors RX, SX, and SFX may include a reset transistor RX, a select transistor SX, and a source follower transistor SFX. Additionally, each of the pixels PXL may include a photoelectric conversion element PD and a floating diffusion region FD.

The photoelectric conversion element PD may generate and accumulate photocharges in proportion to the amount of light incident from the outside. The photoelectric conversion element PD may include a photodiode, a phototransistor, a photogate, a pinned photodiode, or combinations thereof. The transfer transistor TX may transfer the photocharges, generated by the photoelectric conversion element PD, to the floating diffusion region FD. A transfer gate of the transfer transistor TX may be connected to a transfer gate line TGL. The floating diffusion region FD may receive and cumulatively store the photocharges generated by the photoelectric conversion element PD.

A gate of the source follower transistor SFX may be connected to the floating diffusion region FD. A drain terminal of the source follower transistor SFX may be connected to a power supply terminal V_{DD} for supplying a power supply voltage. The source follower transistor SFX may be controlled based on the amount of photocharges accumulated in the floating diffusion region FD.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power supply terminal V_{DD}. When the reset transistor RX is turned on, the power supply voltage from the power supply terminal V_{DD} may be applied to the floating diffusion region FD through the reset transistor RX. For example, when the reset transistor RX is turned on, the charges accumulated in the floating diffusion region FD may be discharged by the power supply voltage to reset the floating diffusion region FD.

The source follower transistor SFX may serve as a source follower buffer amplifier. The source follower transistor SFX may amplify a potential variation in the floating diffusion region FD and output the amplified potential variation to an output line V_{OUT}.

A gate of the select transistor SX may be connected to a select gate line SGL. A drain terminal of the select transistor SX may be connected to a source terminal of the source follower transistor SFX, and a source terminal of the select transistor SX may be connected to the output line V_{OUT}. The select transistors SX of the pixels PXL to be read in units of rows may be selected by a select signal applied through the corresponding select gate lines SGL. When the select transistor SX is turned on, the potential variation amplified by the source follower transistor SFX may be output to the output line V_{OUT} through the select transistor SX.

Each of the pixels PXL includes a single photoelectric conversion device PD as illustrated in FIG. 2, but embodiments are not limited thereto. In one or more embodiments, a plurality of pixels PXL may share the floating diffusion region FD and logic transistors RX, SX, and SFX. For example, a plurality of photoelectric conversion devices PD and a plurality of corresponding transfer transistors TX may share the floating diffusion region FD and logic transistors RX, SX, and SFX.

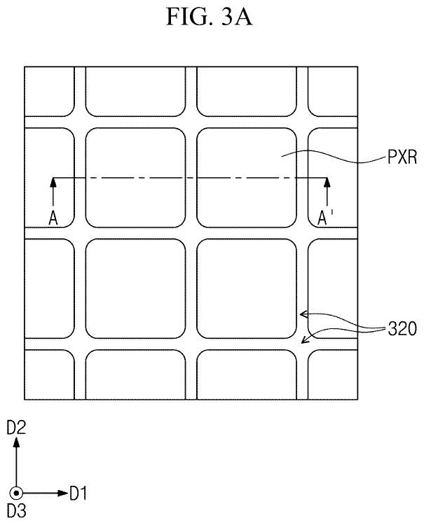

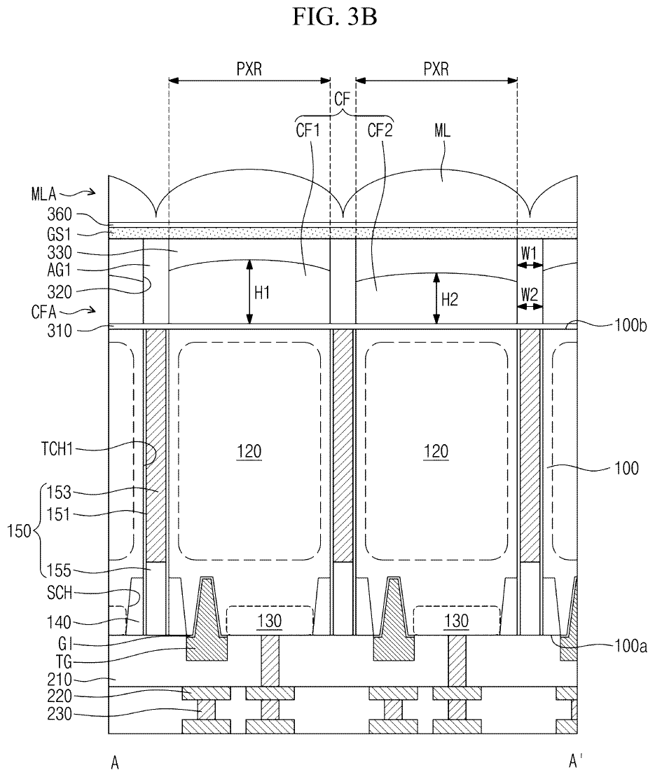

FIG. 3A is a plan view of a grid recess and pixel regions according to one or more embodiments. FIG. 3B is a cross-sectional view taken along line A-A′ of FIG. 3A.

Referring to FIG. 3A and FIG. 3B, the image sensor according to one or more embodiments may include a substrate 100, a transmissive insulating layer 310, color filters CF, planarization patterns 330, a grid recess 320, a first air gap AG1, a first glass substrate GS1, a photoelectric conversion region 120, a first deep isolation pattern 150 (i.e., a first isolation pattern), a shallow isolation pattern 140 (i.e., a shallow trench isolation pattern), a transfer gate TG, and a floating diffusion region 130.

The substrate 100 may have a first surface 100a and a second surface 100b opposing each other. The first surface 100a of the substrate 100 may be a front surface, and the second surface 100b of the substrate 100 may be a rear surface. In one or more embodiments, the first surface 100a may correspond to an active surface at which various transistors of the pixels PXL are formed. Light may be incident on the second surface 100b of the substrate 100. For example, the second surface 100b may be a light incident surface.

The substrate 100 may include a semiconductor substrate (for example, a silicon substrate, a germanium substrate, or a silicon-germanium substrate) or a silicon-on-insulator (SOI) substrate. The substrate 100 may include impurities of a first conductivity type. Therefore, the substrate 100 may have the first conductivity type. The impurities of the first conductivity type may be group III elements. For example, the impurities of the first conductivity type may be P-type impurities such as boron (B).

The substrate 100 may be provided with a plurality of pixel regions PXR. Although only one pixel region PXR is illustrated in FIG. 3B, embodiments are not limited thereto and a plurality of pixel regions PXR may be arranged in a matrix of rows and columns. The pixel region PXR may correspond to the pixel PXL of FIG. 2.

The transmissive insulating layer 310 may cover the second surface 100b of the substrate 100. The transmissive insulating layer 310 may have a single-layer structure or a multilayer structure. In one or more embodiments, the transmissive insulating layer 310 may include a fixed charge film, an antireflection layer, or a composite stack thereof.

The fixed charge film may have negative fixed charges. Thus, holes may be accumulated near the fixed charge layer, for example, at an interface between the fixed charge layer and the substrate 100 and/or in a portion of the substrate 100 adjacent to the second surface 100b. As a result, the fixed charge layer may effectively reduce dark current and/or white spots. In one or more embodiments, the fixed charge layer may be formed of a metal oxide or metal fluoride containing at least one of hafnium (Hf), zirconium (Zr), aluminum (Al), tantalum (Ta), titanium (Ti), yttrium (Y), or lanthanoids. For example, the fixed charge layer may be formed of hafnium oxide or aluminum oxide.

The antireflection layer may reduce or significantly reduce the reflection of light incident on the second surface 100b. For example, the antireflection layer may include at least one of titanium oxide, silicon nitride, silicon oxide, or hafnium oxide. When the transmissive insulating layer 310 includes the fixed charge layer and the antireflection layer (i.e., a composite stack thereof), the fixed charge layer may be in contact with the second surface 100b of the substrate 100 and the antireflection layer may be disposed on the fixed charge layer. However, embodiments are not limited thereto. In one or more embodiments, the transmissive insulating layer 310 may include either the fixed charge layer or the antireflection layer, or may further include an additional insulating layer. The term “contact,” as used herein, refers to a direct connection (i.e., physical touching) unless the context indicates otherwise.

The color filters CF may be provided on the transmissive insulating layer 310. The color filters CF may be disposed on the pixel regions PXR, respectively. The color filters CF may be arranged two-dimensionally on the transmissive insulating layer 310. The color filters CF arranged two-dimensionally may constitute a color filter array CFA.

According to some embodiments, four pixels PX arranged in a 2×2 matrix may implement the same color. Alternatively, each of the four pixels PX arranged in a 2×2 matrix may implement one of red, green, or blue colors. For example, the four pixels PX may sequentially implement red, green, green, and blue colors.

The color filters CF may be arranged on the second surface 100b of the substrate 100 for each pixel region PXR. For example, the color filters CF may be provided at locations corresponding to the photoelectric conversion regions 120, respectively. Each of the color filters CF may be allocated to one of a plurality of reference colors. The plurality of reference colors may include, for example, red-green-blue (RGB), red-green-blue-white (RGBW), cyan-magenta-yellow (CMY), cyan-magenta-yellow-black (CMYK), red-yellow-blue (RYB), or RGB IR ray (RGBIR). However, the color of the color filters CF is not limited thereto, and filters of other colors may also be provided.

In one or more embodiments, the color filters CF may include a first color filter CF1 and a second color filter CF2 having different heights relative to an upper surface of the transmissive insulating layer 310. For example, as illustrated in FIG. 3B, the height H1 of the first color filter CF1 may be greater than the height H2 of the second color filter CF2. The heights H1 and H2 may be defined as the distances from the upper surface of the transmissive insulating layer 310 to the respective uppermost surfaces of the first color filter CF1 and the second color filter CF2.

In one or more embodiments, the colors of the first color filter CF1 and the second color filter CF2 may be different from each other. For example, the first color filter CF1 and the second color filter CF2 may transmit light of different wavelengths. For example, the first color filter CF1 may be a red color filter, and the second color filter CF2 may be a blue color filter. Therefore, the heights of the color filters CF having different colors may also be different from each other.

The planarization patterns 330 may be provided on the color filters CF. For example, the planarization patterns 330 may cover upper surfaces of the color filters CF. Each of the planarization patterns 330 may have a flat upper surface. For example, each of the planarization patterns 330 may have an upper surface having a constant height relative to the upper surface of the transmissive insulating layer 310 or the second surface 100b of the substrate 100.

In one or more embodiments, the upper surface of the planarization pattern 330 on the first color filter CF1 may be at substantially the same level as the upper surface of the planarization pattern 330 on the second color filter CF2. Therefore, the planarization patterns 330 provided on the color filters CF with different heights

### May Perform a Function of Planarizing Upper Portions of the Color Filters Cf to Ensure

smooth subsequent processes. For example, the planarization patterns 300 may serve to establish a planarized surface that facilitates subsequent fabrication processes.

In one or more embodiments, the planarization patterns 330 may include silicon oxide (SiO₂), titanium oxide (TiO₂), aluminum oxide (Al₂O₃), tantalum oxide (Ta₂O₅), hafnium oxide (HfO₂), or combinations thereof. In addition, the planarization patterns 330 may include at least one organic material, for example, an organic polymer. The organic polymer may include, for example, epoxy resin, polyimide, polycarbonate, polyacrylic, polymethyl methacrylate (PMMA), or combinations thereof, but embodiments are not limited thereto.

The grid recess 320 may be provided between the color filters CF. Additionally, the grid recess 320 may be provided between the planarization patterns 330. The grid recess 320 may be a recessed portion extending from the upper surfaces of the planarization patterns 330 to lower surfaces of the color filters CF. For example, the grid recess 320 may pass between the color filters CF and between the planarization patterns 330.

The grid recess 320 may guide incident light into the photoelectric conversion region 120. When viewed in a plan view, the grid recess 320 may have a grid shape with openings. A cross-section of the grid recess 320 may have a quadrilateral shape. For example, the cross-section of the grid recess 320 may be rectangular. Thus, an upper width W1 of the grid recess 320 may be substantially the same as a lower width W2 of the grid recess 320. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

In one or more embodiments, the grid recess 320 may vertically overlap the first deep isolation pattern 150. However, embodiments are not limited thereto. In one or more embodiments, the grid recess 320 may have a structure, laterally offset from the first deep isolation pattern 150. The offset structure may be intentionally selected to optimize an optical path in consideration of a manufacturing process margin and/or an angle at which incident light travels.

A first air gap AG1 may be provided inside the grid recess 320. The first air gap AG1 may be defined by an internal space of the grid recess 320. For example, the first air gap AG1 may be the internal space of the grid recess 320 filled with air.

In one or more embodiments, an upper width W1 of the first air gap AG1 may be substantially the same as a lower width W2 of the first air gap AG1.

In one or more embodiments, the image sensor may reduce crosstalk by providing the first air gap AG1 within the grid recess 320. For example, the first air gap AG1 is an air-filled space, leading to a lower refractive index than that of tungsten W or silicon oxide (SiOₓ). Accordingly, light loss caused by interference of incident light with adjacent pixel regions PXR may be significantly reduced. As a result, the photoelectric conversion efficiency of the image sensor may be improved.

The first glass substrate GS1 may be provided on the upper surfaces of the planarization patterns 330. The first glass substrate GS1 may close an upper end of the first air gap AG1. For example, the first glass substrate GS1 may seal the first air gaps AG1.

The first glass substrate GS1 may be, for example, a flat substrate formed of glass. The first glass substrate GS1 may have, for example, a disk shape when viewed in a plan view.

The photoelectric conversion region 120 may be provided within the substrate 100. The photoelectric conversion region 120 may correspond to pixel regions PXR of the substrate 100, respectively. The photoelectric conversion region 120 may correspond to the photoelectric conversion element PD described above in FIG. 2. The photoelectric conversion region 120 may be interposed between the first surface 100a and the second surface 100b of the substrate 100. The photoelectric conversion region 120 may be disposed at a location spaced apart from the second surface 110b of the substrate 100.

The photoelectric conversion region 120 may be a doped region containing impurities of a second conductivity type. The second conductivity type may be opposite to the first conductivity type. In one or more embodiments, the photoelectric conversion regions 120 may include Group V elements, which may be impurities of the second conductivity type. The impurities of the second conductivity type may include N-type impurities such as phosphorus, arsenic, bismuth, and/or antimony.

The first deep isolation pattern 150 may be formed in the substrate 100. The first deep isolation pattern 150 may separate and divide the pixel regions PXR. For example, the first deep isolation pattern 150 may be provided between the pixel regions PXR of the substrate 100. For example, the first deep isolation pattern 150 may define the pixel regions PXR.

The first deep isolation pattern 150 may penetrate through the substrate 100. For example, the first deep isolation pattern 150 may extend from the first surface 100a of the substrate 100 to the second surface 100b of the substrate 100, and may penetrate the shallow isolation pattern 140. In addition, the first deep isolation pattern 150 may be provided in the first deep trench TCH to separate the pixel regions PXR.

The first deep trench TCH1 may be recessed from either the first surface 100a or the second surface 100b of the substrate 100.

In one or more embodiments, the first deep isolation pattern 150 may include a first insulating liner 151, a first embedded conductive pattern 153, and a first capping pattern 155. As will be described later, the configuration of the first deep isolation pattern 150 may vary according to embodiments.

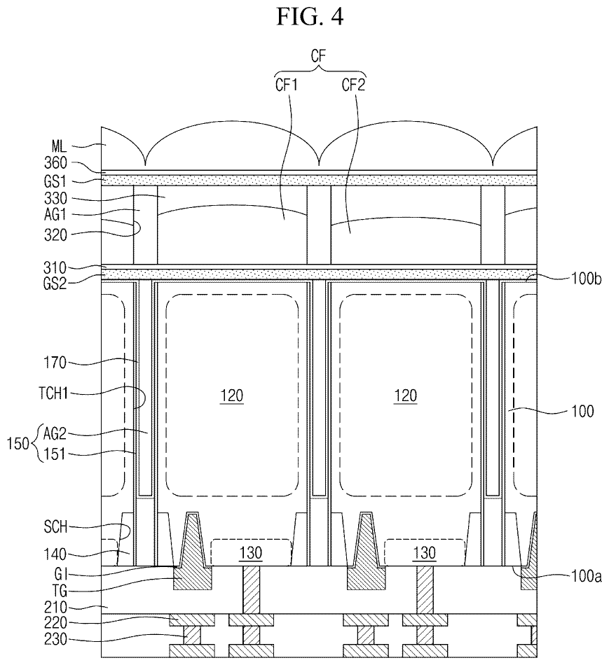

The first insulating liner 151 may be provided along an inner wall of the first deep trench TCH1. The first insulating liner 151 may cover all sidewalls of the first deep trench TCH1 penetrating through the substrate 100. For example, the first deep trench TCH1 may extend from the first surface 100a of the substrate 100 to the second surface 100b of the substrate 100, and may penetrate the shallow isolation pattern 140. The first insulating liner 151 may be provided between the substrate 100 and the first embedded conductive pattern 153 to electrically insulate the substrate 100 from the first embedded conductive pattern 153. However, the role of the first insulating liner 151 is not limited thereto. As will be described later, in certain cases, a first insulating layer 170 (see FIG. 4) may substitute for the role of the first insulating liner 151.

The first insulating liner 151 may include an insulating material, for example, a silicon-based insulating material such as silicon nitride (Si₃N₄), silicon oxide (SiO₂), silicate, and/or silicon carbon nitride (SiCN) and/or a high-κ metal oxide such as hafnium oxide (HfOₓ), zirconium oxide (ZrO₂), titanium oxide (TiO₂), or aluminum oxide (Al₂O₃, alumina).

In one or more embodiments, although the first insulating liner 151 is illustrated as being formed as a single layer, embodiments are not limited thereto. Alternatively, the first insulating liner 151 may include a plurality of layers, which may include different materials.

The first insulating liner 151 may be formed of a material having a lower refractive index than the substrate 100. Accordingly, crosstalk between pixels may be prevented and/or reduced.

The first embedded conductive pattern 153 may be provided to a predetermined depth from the second surface 100b. In one or more embodiments, a lower surface of the first embedded conductive pattern 153 may be disposed higher than a second surface, closer to the second surface 100b of the substrate 100, of the shallow isolation pattern 140. A first surface of the shallow isolation pattern 140 may be exposed at the first surface 100a of the substrate 100. The present disclosure is not limited thereto. In one or more embodiments, the lower surface of the embedded conductive pattern 153 may be disposed at the same level as the upper surface of the shallow isolation pattern 140 or may be disposed below the upper surface of the shallow isolation pattern 140. In one or more embodiments, a length of the first embedded conductive pattern 153 in a direction from the second surface 100b to the first surface 100a (i.e., a vertical direction perpendicular to the second surface 100b of the substrate 100) may be set in various ways.

The first embedded conductive pattern 153 may be formed of a material including doped polysilicon or metal. A dopant for the doped polysilicon may include a first conductivity type (for example, P-type) impurity or a second conductivity type (for example, N-type) dopant. For example, the first embedded conductive pattern 153 may include polysilicon doped with boron (B). Alternatively, the first embedded conductive pattern 153 may include polysilicon doped with phosphorus (P) or arsenic (As). In one or more embodiments, the impurity doped in the first embedded conductive pattern 153 may improve electrical conductivity of the first embedded conductivity pattern 153. Improving the electrical conductivity of the first embedded conductive pattern 153 may enhance the negative bias application efficiency of the first deep isolation pattern 150, resulting in improved photo-detection sensitivity. For example, when a negative bias voltage is applied to the first embedded conductive pattern 153, improving of the electrical conductivity thereof may allow more efficient biasing of the first deep isolation pattern 150, thereby enhancing the photo-detection sensitivity.

When the first embedded conductive pattern 153 includes metal, copper, tungsten, aluminum, titanium, or the like, may be used. However, the metal is not limited thereto, and other conductive materials such as various metals, doped organic/inorganic materials, or combinations thereof may also be used. Other conductive materials may include, for example, conductive metal oxides, metal grids, random metal networks, carbon nanotubes, graphene, nanowire meshes, ultra-Thin metal films, or conductive polymers.

The first buried conductive pattern 153 may be formed using thin film deposition, epitaxial growth, impurity doping, or the like. For example, a conductive oxide such as indium tin oxide, metal, or the like, may be formed by physical or chemical deposition. Doped polysilicon may be formed by deposition or by epitaxial growth with dopants such as boron, phosphorus, or arsenic.

The first capping pattern 155 may cover a lower surface of the first buried conductive pattern 153 and may be adjacent to the first surface 100a of the substrate 100. The first capping pattern 155 may include an insulating material, for example, a silicon-based insulating material such as silicon nitride (Si₃N₄), silicon oxide (SiO₂), silicon oxynitride, and/or silicon carbonitride (SiCN), and/or a high-κ metal oxide such as hafnium oxide (HfOₓ), zirconium oxide (ZrO₂), and/or aluminum oxide (Al₂O₃).

The shallow isolation pattern 140 may be provided in the substrate 100 to define active regions. The shallow isolation pattern 140 may be buried inward from the first surface 100a of the substrate 100. In addition, the first surface of the shallow isolation pattern 140 may be exposed at the first surface 110a of the substrate 100.

The shallow isolation pattern 140 may fill a shallow trench SCH recessed into the substrate 100 from the first surface 100a. Accordingly, the shallow isolation pattern 140 may be adjacent to the first surface 100a of the substrate 100.

The shallow isolation pattern 140 may be provided between active regions to electrically isolate the active regions within the substrate 100. Each of the active regions may be defined within respective pixel regions PXR. When viewed in a plan view, the active regions may be portions of the substrate 100 surrounded by the shallow isolation pattern 140.

The shallow isolation pattern 140 is adjacent to the first deep isolation pattern 150. In certain embodiments, the shallow isolation pattern 140 may be connected to the first deep isolation pattern 140. The shallow isolation pattern 140 may be formed of various insulating materials. For example, the shallow isolation pattern 140 may include at least one of silicon oxide, silicon nitride, or silicon oxynitride.

In one or more embodiments, the first deep trench TCH may be connected to the shallow trench SCH. For example, the first insulating liner 151 and the first capping pattern 155 of the first deep isolation pattern 150 and the shallow isolation pattern 140 may be filled with the same material.

According to one or more embodiments, the first deep isolation pattern 150 and the shallow isolation pattern 140 may be modified in various ways within the inventive concept. Embodiments to be described later are some of the various modifications within the inventive concept and may be combined with each other within the limit of compatibility.

The transfer gate TG may be disposed on the first surface 100a of the substrate 100, and may be disposed on a corresponding active region of each of the pixel regions PXR. A gate insulating layer GI may be disposed between the transfer gate TG and the corresponding active region. In one or more embodiments, the transfer gate TG may fill a gate trench recessed into the corresponding active region from the first surface 100a. The gate insulating layer GI may also extend to be disposed between the transfer gate TG and an inner surface of the gate trench. When the transfer gate TG fills the gate trench, a transfer transistor including the transfer gate TG may be a vertical channel transistor.

A floating diffusion region 130 may be provided in the corresponding active region on one side of the transfer gate TG. The floating diffusion region 130 may be a region doped with impurities. The floating diffusion region 130 may include second conductivity-type impurities. When light is incident into the photoelectric conversion region 120, photocharges may be generated from a depletion region at a boundary between the photoelectric conversion region 120 and the substrate 100 and accumulated within the floating diffusion region 130. For example, when the transfer transistor is turned on, the generated photocharges may be transferred to the floating diffusion region 130 through the transfer transistor. The floating diffusion region 130 may correspond to the floating diffusion region FD illustrated in FIG. 2.

An upper passivation layer 360 (i.e., an upper protective layer) may be disposed between the first glass substrate GS1 and microlenses ML. The upper passivation layer 360 may cover the upper surface of the first glass substrate GS1.

The upper passivation layer 360 may be formed of an insulating material. For example, the upper passivation layer 360 may include a silicon-based insulating material (for example, silicon oxide, silicon nitride, and/or silicon oxynitride) and/or a high-κ dielectric material (for example., hafnium oxide and/or aluminum oxide).

The upper passivation layer 360 may include a plurality of layers. For example, the upper passivation layer 360 may include an antireflection layer. The antireflection layer may be formed of various materials. Examples of the various materials include hafnium oxide (HfOₓ), zirconium oxide (ZrO2), titanium oxide (TiO2), aluminum oxide (Al2O3), alumina, or the like. The upper passivation layer 360 may prevent the reflection of light incident on the second surface 100b of the substrate 100, enabling the light to reach the photoelectric conversion region 120 without obstruction.

The microlenses ML may be disposed on the upper passivation layer 360. At least a portion of the microlenses ML may be disposed to vertically overlap the photoelectric conversion regions 120. The microlenses ML are intended to focus light incident in the direction of the substrate 100, and may be spherical lenses, aspherical lenses, or a combination thereof. The microlenses ML may be provided at positions corresponding to the photoelectric conversion regions 120 of the substrate 100. The microlenses ML may be arranged two-dimensionally to constitute a microlens array MLA.

The microlens ML may be transparent, allowing light to pass therethrough. The microlens ML may include an organic material such as polymer. For example, the microlens ML may include a photoresist material or a thermosetting resin.

In one embodiment, the microlenses ML may be disposed in each pixel region PXR, but embodiments are not limited thereto. The microlenses ML may have an offset structure slightly shifted from the position corresponding to each pixel region PXR. Such an offset structure may be due to the process margin of the microlenses ML, or may be intentionally selected to optimize an optical path in consideration of an angle of light incident from outside into the pixel region PXR, or the like.

The microlenses ML may be provided on the color filters CF. The microlenses ML may focus incident light. As illustrated in FIG. 3B, the microlenses ML may be vertically aligned with the respective photoelectric conversion regions 120.

Alternatively, each of the microlenses ML may be vertically aligned with a corresponding one of the photoelectric conversion regions 120. For example, each of the microlenses ML may be vertically aligned with photoelectric conversion regions 120 arranged in a 2×2 matrix, a 3×3 matrix, or a 4×4 matrix.

Each of the microlenses ML may have a convex shape in cross-section view. In certain embodiments, each of the microlenses ML may have a circular or elliptical shape when viewed in a plan view. The microlenses ML may be formed of a light-transmissive resin.

Although not illustrated, an additional protective layer may be provided on the surfaces of the microlenses ML. The additional protective layer may protect the microlenses ML and allow light to pass therethrough. The additional protective layer may be formed of an organic material and/or an inorganic material. For example, the additional protective layer may include at least one of silicon oxide, silicon nitride, silicon oxynitride, silicon carbide, silicon oxycarbide, silicon carbonitride, silicon carbonoxynitride, aluminum oxide, zinc oxide, or hafnium oxide.

As illustrated in FIG. 3B, the grid recess 320 may be vertically aligned with the first deep isolation pattern 150, and each of the microlenses ML and each of the color filters CF may be vertically aligned with a corresponding photoelectric conversion region 120. However, embodiments are not limited thereto. The image sensor according to one or more embodiments may further include interlayer dielectric layers 210, wirings 220, and contact plugs 230. The interlayer dielectric layers 210 may be disposed on the first surface 100a of the substrate 100 and cover the transfer gate TG, the floating diffusion region 130, the shallow isolation pattern 140, and the first deep isolation pattern 150. The wirings 220 and the contact plugs 230 may be arranged in the interlayer dielectric layers 210 to be connected to the floating diffusion region 130 and the transfer gate TG.

FIG. 4 is a cross-sectional view of an image sensor according to one or more embodiments. For brevity, the following description will focus on differences from the above-described embodiment.

Referring to FIG. 4, the image sensor according to one or more embodiments may further include a second air gap AG2, a second glass substrate GS2, and a first insulating layer 170.

In one or more embodiments, the first deep isolation pattern 150 may include a first insulating liner 151, a portion of the first insulating layer 170, and the second air gap AG2. The first buried conductive pattern 153 (see FIG. 3B) may be omitted.

The second air gap AG2 may be provided inside the first trench TCH1. The second air gap AG2 may be defined by an internal space of the first trench TCH1. For example, the second air gap AG2 may be the internal space of the first trench TCH1 filled with air.

The image sensor according to one embodiment may reduce crosstalk by providing the second air gap AG2 inside the first trench TCH1. For example, the second air gap AG2 is an air-filled space, leading to a lower refractive index than that of a metal material or silicon oxide. Accordingly, the photoelectric conversion efficiency of the image sensor may be improved.

The first insulating layer 170 may be provided on the second surface 100b of the substrate and on an inner surface of the first deep trench TCH1. The first insulating layer 170 may be provided between the second air gap AG2 and the first insulating liner 151. The first insulating layer 170 may be conformally provided on the inner surface of the first deep trench TCH1 and the second surface 100b of the substrate 100.

The first insulating layer 170 may be provided between the second glass substrate GS2 and the substrate 100 to facilitate adhesion of the second glass substrate GS2 to the substrate 100. For example, the first insulating layer 170 may serve as an adhesion assist layer for the second glass substrate GS2.

The first insulating layer 170 may include a silicon-based insulating material, a low-κ dielectric material, or a combination thereof. For example, the first insulating layer 170 may include silicon oxide (SiO₂), silicate, silicon carbonitride (SiCN), silicon oxyfluoride (SiOF), or combinations thereof. However, embodiments are not limited thereto, and the first insulating layer 170 may include various other materials.

The second glass substrate GS2 may be provided on the second surface 100b of the substrate 100. The second glass substrate GS2 may be provided on the first insulating layer 170. The second glass substrate GS2 may be provided on the lower surface of the transmissive insulating layer 310. For example, the second glass substrate GS2 may be provided between the first insulating layer 170 and the transmissive insulating layer 310.

The second glass substrate GS2 may close upper ends of the second air gaps AG2. For example, the second glass substrate GS2 may seal the second air gaps AG2.

The second glass substrate GS2 may be, for example, a flat substrate formed of glass. The second glass substrate GS2 may have, for example, a circular shape when viewed in a plan view.

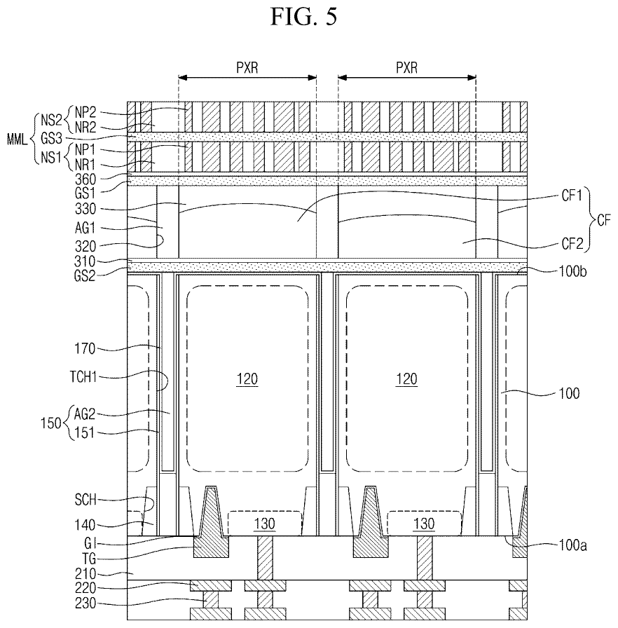

FIG. 5 is a cross-sectional view of an image sensor according to one or more embodiments. For brevity, the following description will focus on differences from the above-described embodiments.

Referring to FIG. 5, an image sensor according to one or more embodiments may further include meta-microlenses MML, unlike the embodiment of FIG. 4 including the microlenses ML.

The meta-microlenses MML may be provided on the upper protective layer 360. Each of the meta-microlenses MML may cover a corresponding pixel region PXR. As planar microlenses, the meta-microlenses MML may be arranged on the color filters CF.

Each of the meta-microlenses MML may include sub-wavelength periodic nanostructures to locally control a refractive index of the meta-microlens MML. The nanostructures may control the polarization, phase, and magnitude of light by locally adjusting the refractive index of the meta-microlens MML. For example, the nanostructures may locally adjust a ratio of materials having different refractive indices in regions, through which light passes, to control a phase delay of transmitted light. The meta-microlenses MML may include a plurality of nanostructures, and may locally control the refractive index of the meta-microlenses MML through the nanostructures.

In one or more embodiments, each of the meta-microlenses MML may include a first nanostructure layer NS1, a third glass substrate GS3, and a second nanostructure layer NS2. In the present disclosure, the third glass substrate GS3 may also be referred to as a meta glass substrate GS3.

The first nanostructure layer NS1 may include a plurality of first nanoposts NP1 and a first nanorefractive pattern NR1. The first nanoposts NP1 have a pillar shape and may be spaced apart from each other by the first nanorefractive pattern NR1. For example, when viewed in a plan view, the first nanorefractive pattern NR1 may surround each of the first nanoposts NP1. A diameter and arrangement of the first nanoposts NP1 may vary depending on a location at which the meta-microlens MML is provided.

The first nanostructure layer NS1 may be formed of two or more materials having different refractive indices. For example, the first nanoposts NP1 may be formed of materials having a relatively high refractive index, while the first nanorefractive pattern NR1 may be formed of materials having a relatively low refractive index.

For example, the first nanoposts NP1 may include dielectric materials having a high refractive index and low absorption in the visible wavelength range, such as TiO₂, GaN, ZnS, ZnSe, or SiNx (for example, Si₃N₄). The first nanorefractive pattern NR1 may include dielectric materials having a relatively low refractive index and low absorption in the visible range, such as SiO₂, SiCOH, siloxane-based spin-on glass (SOG), or air.

At least a portion of the meta-microlenses MML may be arranged to vertically overlap the photoelectric conversion regions 120. The meta-microlenses MML may be provided at locations corresponding to the photoelectric conversion regions 120.

An effective refractive index of the meta-microlens MML may be highest in a certain region of the meta-microlens MML and gradually decrease toward a periphery of the region, allowing each meta-microlens MML to function as a convex lens that converges light. For example, a density of the first nanoposts NP1 to the first nanorefractive pattern NR1 may be highest in a certain region of the meta-microlens MML and gradually decrease toward the periphery of the region.

The meta glass substrate GS3 may be provided on the first nanostructure layer NS1. The meta glass substrate GS3 may have substantially the same shape and be formed of substantially the same material as the above-described first and second glass substrates GS1 and GS2.

The second nanostructure layer NS2 may be provided on the meta glass substrate GS3. The second nanostructure layer NS2 may include a plurality of second nanoposts NP2 and a second nanorefractive pattern NR2. The second nanoposts NP2 have a pillar shape and may be spaced apart from each other by the second nanorefractive pattern NR2. For example, when viewed in a plan view, the first nanorefractive pattern NR2 may surround each of the second nanoposts NP2. A diameter and arrangement of the second nanoposts NP2 may vary depending on a location at which the meta-microlens MML is provided.

The second nanoposts NP2 and the second nanorefractive pattern NR2 may be formed of substantially the same materials as the above-described first nanoposts NP1 and the first nanorefractive pattern NR1.

The meta glass substrate GS3 having a flat surface may be disposed between the first and second nanostructure layers NS1 and NS2 to suppress optical distortion.

In one or more embodiments, a passivation layer, not illustrated, may be provided on the meta-microlenses MML. The passivation layer may be formed to have a single-layer structure or a multilayer structure. The passivation layer may serve not only as a protective layer that protects the meta-microlenses MML but also as an antireflection pattern that prevents external light from being reflected on upper surfaces of the meta-microlenses MML while allowing light to pass therethrough.

The passivation layer may include various materials, such as hafnium oxide, silicon oxide, silicon nitride, silicon oxynitride, silicon carbide, silicon oxycarbide, silicon carbon oxynitride, zirconium oxide, titanium oxide, and/or aluminum oxide (Al₂O₃, alumina). The passivation layer may prevent the reflection of light such that light, traveling toward the second surface 100b of the substrate 100 through the meta-microlenses MML, efficiently reaches the photoelectric conversion regions 120.

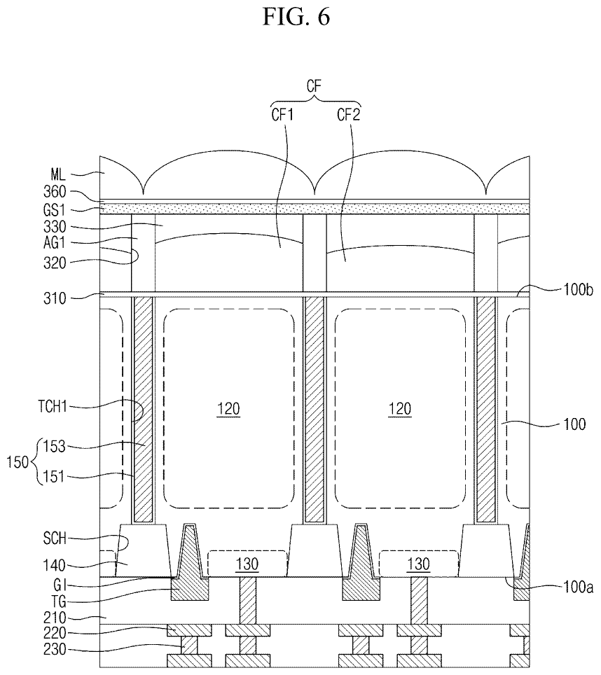

FIG. 6 is a cross-sectional view of an image sensor according to one or more embodiments. For brevity, the following description will focus on differences from the above-described embodiments.

Referring to FIG. 6, a first deep isolation pattern 150 may include a first insulating liner 151 and a first buried conductive pattern 153. For example, the first capping pattern 155 (see FIG. 3B) may be omitted.

In addition, the first insulating liner 151 may be provided on a lower surface of the first buried conductive pattern 153. For example, the first insulating liner 151 may be provided on inner sidewalls and a bottom surface of a first trench TCH1.

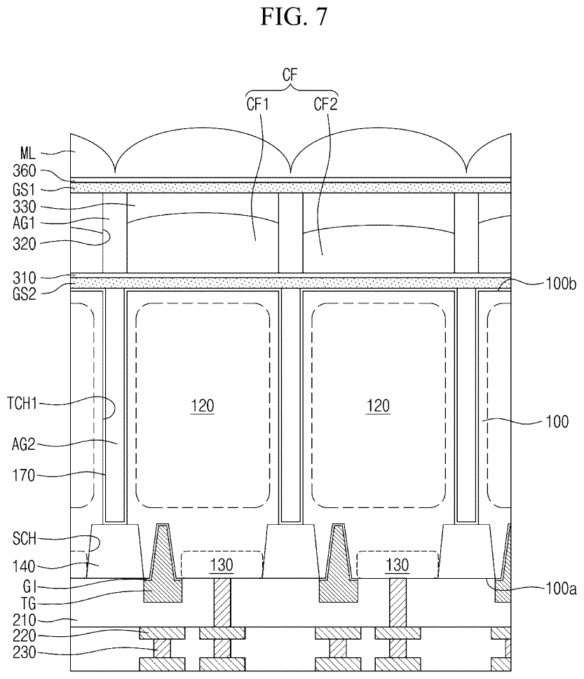

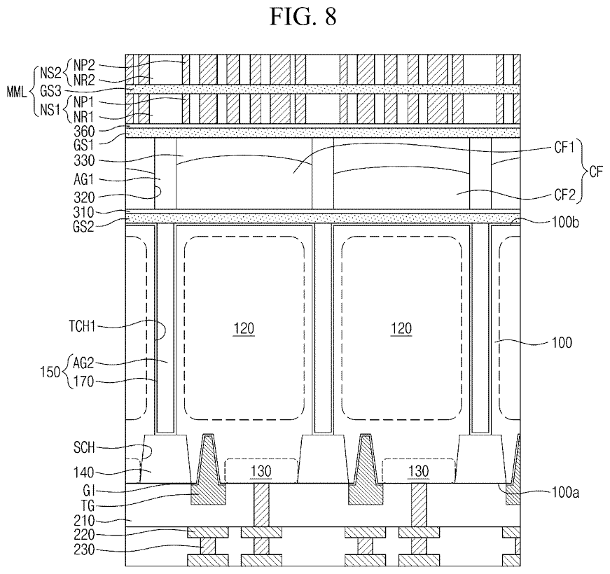

FIGS. 7 and 8 are cross-sectional views of an image sensor according to some embodiments. For brevity, the following description will focus on differences from the above-described embodiments.

Referring to FIGS. 7 and 8, a first deep isolation pattern 150 may include a first insulating layer 170 and a second air gap AG2. For example, the first insulating liner 151 (see FIG. 6), the first buried conductive pattern 153 (see FIG. 6), and the first capping pattern 155 (see FIG. 3B) may be omitted.

In addition, the first insulating layer 170 may be provided on a lower end of the second air gap AG2. The first insulating layer 170 may be provided on inner sidewalls and a bottom surface of a first trench TCH1. For example, the first insulating layer 170 may be conformally provided on an inner surface of the first trench TCH1 and on the second surface 100b of the substrate 100.

As illustrated in FIG. 7, microlenses ML may be provided on an upper protective layer 360. As illustrated in FIG. 8, meta-microlenses MML may also be provided on the upper protective layer 360.

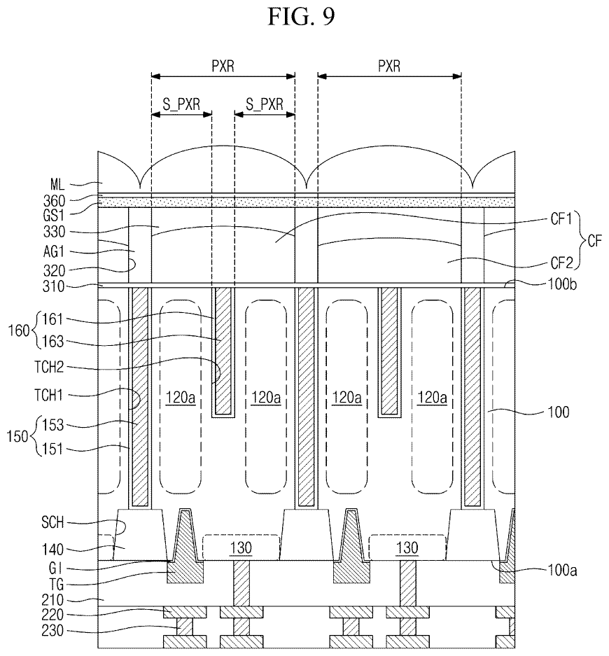

FIG. 9 is a cross-sectional view of an image sensor according to one or more embodiments. For brevity, the following description will focus on differences from the above-described embodiments.

Referring to FIG. 9, the image sensor according to one or more embodiments may further include a second deep isolation pattern 160 (i.e., a second isolation pattern). The second deep isolation pattern 160 may be formed within a substrate 100. The second deep isolation pattern 160 may be provided in each pixel region PXR.

The second deep isolation pattern 160 may define a pair of sub-pixel regions S_PXR. The pair of sub-pixel regions S_PXR may be included within the pixel region PXR. For example, the second deep isolation pattern 160 may be provided between the pair of sub-pixel regions S_PXR.

A photoelectric conversion region 120a may be provided in each of the sub-pixel regions S_PXR. In one or more embodiments, the photoelectric conversion regions 120a provided in each of the pair of sub-pixel regions S_PXR may be doped with different materials. For example, the different materials may include second conductivity impurities (e.g., the photoelectric conversion region 120a in the left sub-pixel region doped with phophorous (P) and the photoelectric conversion region 120a in the right sub-pixel region doped with arsenic (As)). However, embodiments are not limited thereto, and the photoelectric conversion regions 120a provided in each of the pair of sub-pixel regions S_PXR may also be doped with substantially the same material.

The second deep isolation pattern 160 may partially penetrate the substrate 100. For example, the second deep isolation pattern 160 may extend from a second surface 100b of the substrate 100 toward the first surface 100a of the substrate 100, but does not contact the first surface 100a. In addition, the second deep isolation pattern 160 may be provided within a second deep trench TCH2.

The second deep trench TCH2 may be recessed from the second surface 100b of the substrate 100 toward the first surface 100a of the substrate 100. Thus, a bottom surface of the second deep isolation pattern 160 may be disposed at a level between the first surface 100a and the second surface 100b of the substrate 100. For example, the bottom surface of the second deep isolation pattern 160 may be vertically spaced apart from the first surface 100a.

In one or more embodiments, the second deep isolation pattern 160 may include a second insulating liner 161 and a second buried conductive pattern 163. As will be described later, the configuration of the second deep isolation pattern 160 may vary according to embodiments.

The second insulating liner 161 and the second buried conductive pattern 163 may include substantially the same materials as the first insulating liner 151 (see FIG. 3B) and the first buried conductive pattern 153 (see FIG. 3B).

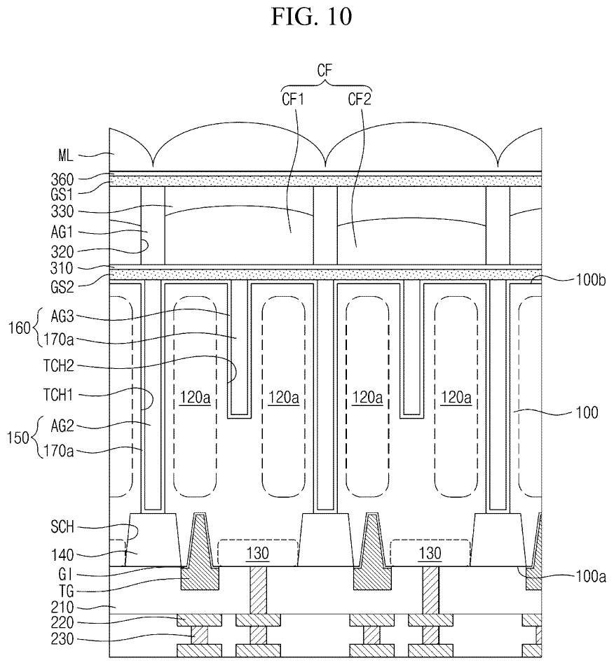

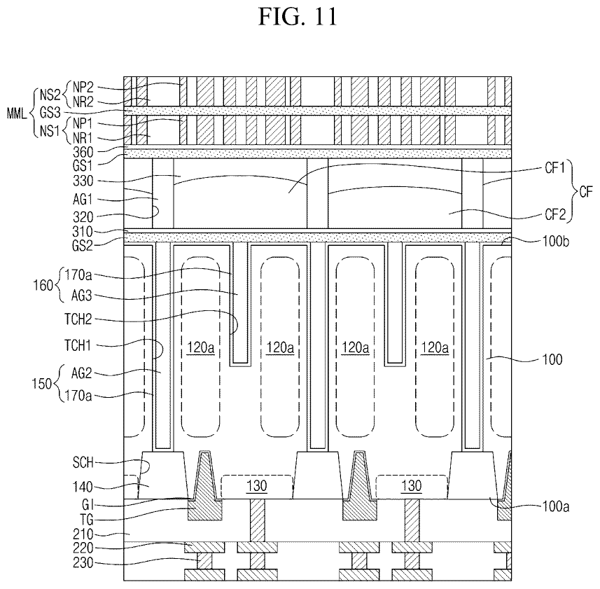

FIGS. 10 and 11 are cross-sectional views of image sensors according to some embodiments. For brevity, the following description will focus on differences from the above-described embodiments.

Referring to FIGS. 10 and 11, a second deep isolation pattern 160 may include a first insulating layer 170a and a second air gap AG2. For example, the second insulating liner 161 (see FIG. 9) and the second embedded conductive pattern 163 (see FIG. 9) may be omitted.

A second glass substrate GS2 may cover an upper surface of the first insulating layer 170a. Thus, the second glass substrate GS2 may close an upper end of the second air gap AG2. For example, the second glass substrate GS2 may seal the second air gap AG2.

As illustrated in FIG. 10, microlenses ML may be provided on an upper protective layer 360. As illustrated in FIG. 11, meta-microlenses MML may be provided on the upper protective layer 360.

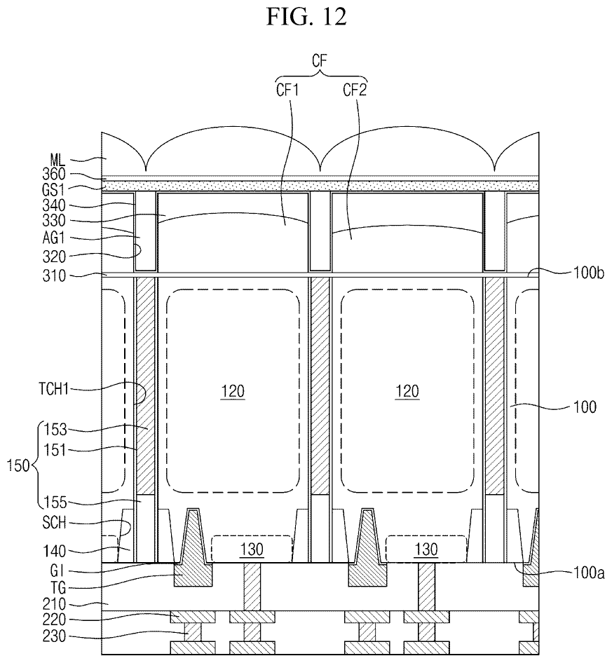

FIG. 12 is a cross-sectional view of an image sensor according to one or more embodiments. For brevity, the following description will focus on differences from the above-described embodiments.

Referring to FIG. 12, the image sensor according to one or more embodiments may further include a grid insulating layer 340.

The grid insulating layer 340 may be provided on an inner surface of a grid recess 320. The grid insulating layer 340 may be provided on upper surfaces of planarization patterns 330. For example, the grid insulating layer 340 may be conformally provided on the inner surface of the grid recess 320 and the upper surfaces of the planarization patterns 330.

A first glass substrate GS1 may be disposed on the grid insulating layer 340. The grid insulating layer 340 may serve to facilitate adhesion of the first glass substrate GS1 to the upper surfaces of the planarization patterns 330. For example, the grid insulating layer 340 may function as an adhesive assist layer between the first glass substrate GS1 and the planarization patterns 330.

The grid insulating layer 340 may include various materials. For example, the grid insulating layer 340 may include silicon oxide, silicon oxynitride, a low-κ dielectric material, or combinations thereof.

In one or more embodiments, refractive indices of color filters CF and a refractive index of the grid insulating layer 340 may each be greater than that of a first air gap AG1. Accordingly, cross-talk between adjacent pixel regions PXR may be reduced.

According to one or more embodiments, the grid insulating layer 340 may be applied in various ways within the inventive concept. For example, the grid insulating layer 340 may also be provided in the embodiments described in FIGS. 3 to 11.

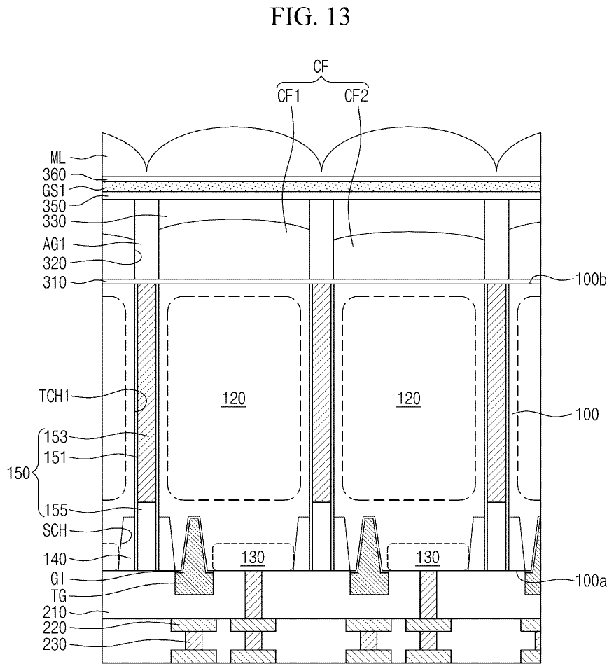

FIG. 13 is a cross-sectional view of an image sensor according to one or more embodiments. For brevity, the following description will focus on differences from the above-described embodiments.

Referring to FIG. 13, the image sensor according to one or more embodiments may further include an adhesive film 350. The adhesive film 350 may be provided on upper surfaces of planarization patterns 330. The adhesive film 350 may be attached to a lower surface of a first glass substrate GS1. For example, the adhesive film 350 may be provided between the first glass substrate GS1 and the planarization patterns 330.

The adhesive film 350 may be attached to the lower surface of the first glass substrate GS1 to enhance adhesion between the first glass substrate GS1 and the planarization patterns 330. For example, the adhesive film 350 may be an insulating resin film.

According to one or more embodiments, the adhesive film 350 may be applied in various ways within the inventive concept. For example, the adhesive film 350 may also be provided in the embodiments described in FIGS. 3 to 12.

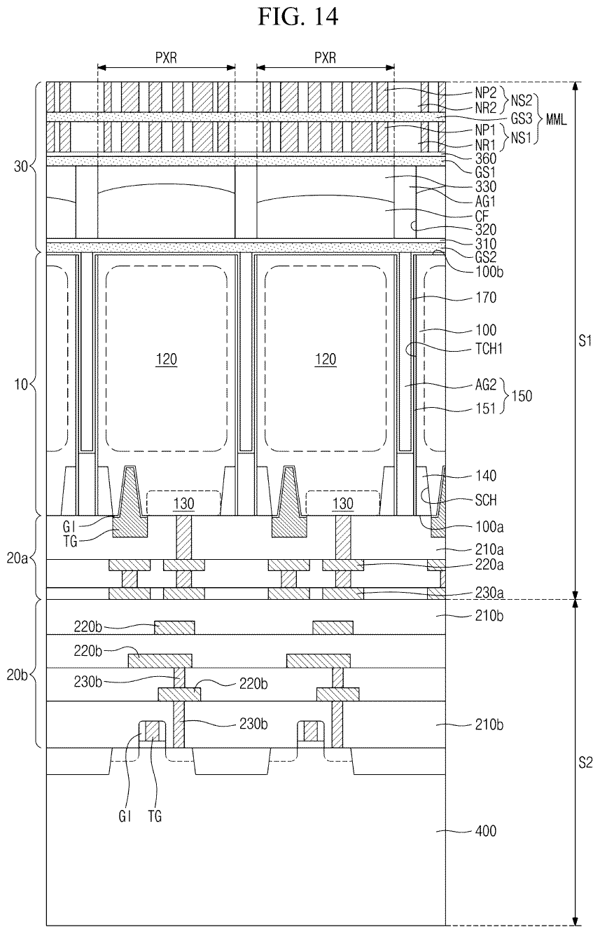

FIG. 14 is a cross-sectional view of an image sensor according to one or more embodiments. For brevity, the following description will focus on differences from the above-described embodiments.

Referring to FIG. 14, an image sensor according to one or more embodiments may include a first structure S1 and a second structure S2. The first structure S1 may be disposed on the second structure S2. The first structure S1 may include a light transmission layer 30, a photoelectric conversion layer 10, and a first circuit wiring layer 20a. The photoelectric conversion layer 10 may be disposed between the light transmission layer 30 and the first circuit wiring layer 20a.

The light transmission layer 30 may include microlenses ML or meta-microlenses MML, color filters CF, planarization patterns 330, grid recesses 320, a first air gap AG1, a first glass substrate GS1, an upper protective layer 360, a second glass substrate GS2, and a transmissive insulating layer 310 as described with reference to FIGS. 3 to 13. The photoelectric conversion layer 10 may include a first substrate 100, a photoelectric conversion region 120, a first deep isolation pattern 150, a shallow isolation pattern 140, a gate insulating layer GI, transfer gates TG, and gates and source/drain regions of logic transistors RX, SX, and DX of FIG. 2. The first circuit wiring layer 20a may include first interlayer dielectric layers 210a, first wirings 220a, and first contact plugs 230a. The first interlayer dielectric layers 210a, the first wirings 220a, and the first contact plugs 230a may correspond to the interlayer dielectric layers 210, the wirings 220, and the contact plugs 230 in FIGS. 3 and 13.

The second structure S2 may include a second substrate 400 and a second circuit wiring layer 20b on the second substrate 400. Peripheral circuit transistors may be formed on the second substrate 400. The second circuit wiring layer 20b may include second interlayer dielectric layers 210b, second wirings 220b, and second contact plugs 230b covering the peripheral circuit transistors. The second wirings 220b and second contact plugs 230b may be provided within the second interlayer dielectric layers 210b and may be electrically connected to the peripheral circuit transistors.

The second structure S2 may include various peripheral circuits (for example, the row decoder 2, the row driver 3, the column decoder 4, the timing generator 5, the correlated double sampler 6, the analog-to-digital converter 7, the input/output buffer 8, the autofocusing circuit, or the like, as described with reference to FIG. 1) to operate pixels in the first structure S1. For example, the second wirings 220b, the second contact plugs 230b, and the peripheral circuit transistors may constitute the various peripheral circuits.

The second circuit wiring layer 20b may be disposed between the first circuit wiring layer 20a and the second substrate 400. A lowermost first interlayer dielectric layer 210a among the first interlayer dielectric layers 210a may be bonded to an uppermost second interlayer dielectric layer 210b among the second interlayer dielectric layers 210b. The first structure S1 may be electrically connected to the second structure S2 through a through-silicon via, not illustrated, in an edge region of the first structure S1. Alternatively, a first bonding pad, not illustrated, may be disposed in the lowermost first interlayer dielectric layer 210a, a second bonding pad, not illustrated, may be disposed in the uppermost second interlayer dielectric layer 210b, and the first bonding pad may be bonded to the second bonding pad. The first structure S1 may be electrically connected to the second structure S2 through the first and second bonding pads. The first and second bonding pads may include copper (Cu).

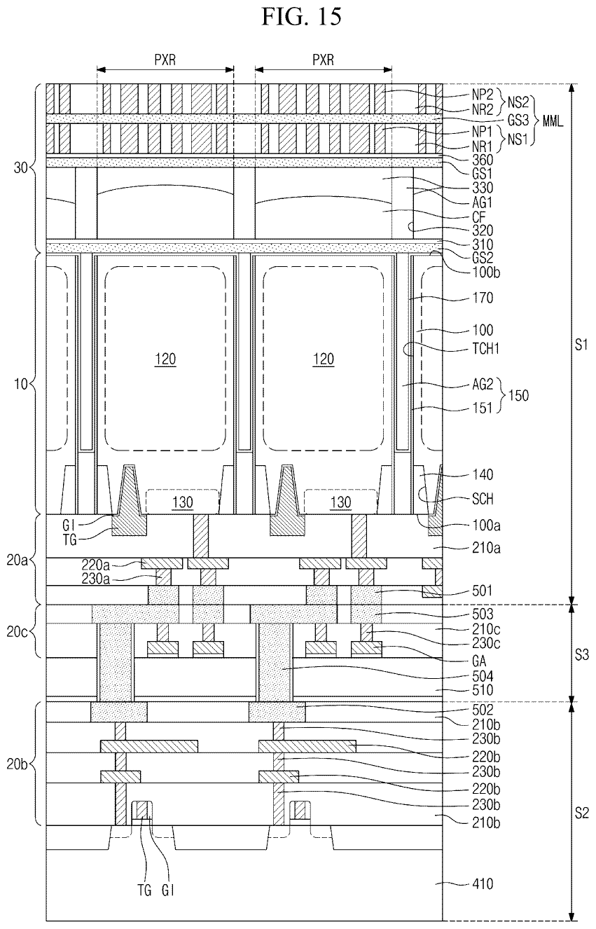

FIG. 15 is a cross-sectional view of an image sensor according to one or more embodiments. For brevity, the following description will focus on differences from the above-described embodiments.

Referring to FIG. 15, the image sensor according to one embodiment may include a first structure S1, a second structure S2, and a third structure S3. The third structure S3 may be disposed between the first structure S1 and the second structure S2.

The first structure S1 may include a light transmission layer 30, a photoelectric conversion layer 10, and a first circuit wiring layer 20a. The light transmission layer 30 may be the same as the light transmission layer 30 of FIG. 14. The photoelectric conversion layer 10 may include a first substrate 100, photoelectric conversion regions 120, first deep isolation patterns 150, shallow isolation patterns 140, gate insulating layers GI, transfer gates TG, and the gates and source/drain regions of logic transistors (RX, SX, and DX of FIG. 2) illustrated in FIGS. 3 to 13. The first circuit wiring layer 20a may include first interlayer dielectric layers 210a, first wirings 220a, first contact plugs 230a, and first bonding pads 501.

The second structure S2 may include a second substrate 400 and a second circuit wiring layer 20b on the second substrate 400. The second structure S2 may be substantially the same as the second structure S2 of FIG. 14. However, the second structure S2 may further include second bonding pads 502 provided in an uppermost second interlayer dielectric layer 210b among the second interlayer dielectric layers 210b.

The third structure S3 may include a third substrate 500, gates GA (i.e., gate electrodes) of transistors on the third substrate 500, and a third circuit wiring layer 20c provided on the third substrate 500. The third substrate 500 may be a semiconductor substrate. Each of the gates GA may be disposed on the third substrate 500 with a gate insulating layer interposed therebetween. Source/drain regions, not illustrated, may be provided in the third substrate 500 on opposite sides of each of the gates GA.

The third circuit wiring layer 20c may include third interlayer dielectric layers 210c, third contact plugs 230c, third bonding pads 503, and fourth bonding pads 504 (i.e., through-silicon vias). Although not illustrated, the third circuit wiring layer 20c may further include third wirings. Each of the third circuit wiring layer 20c may be electrically connected to the corresponding gate GA, source/drain region, third bonding pad 503, and/or fourth bonding pad 504.

According to one or more embodiments, the first structure S1 may include a portion of the components of the pixel PXL of FIG. 2, and the third structure S3 may include another portion of the components of the pixel PXL of FIG. 2. For example, the first structure S1 may include the photoelectric conversion device PD, transfer transistor TX, and floating diffusion region FD of the pixel PXL, and the third structure S3 may include the logic transistors RX, SX, and DX of the pixel PXL.

In one or more embodiments, the logic transistors RX, SX, and DX may be provided on the third substrate 500 below each of the pixel regions PXR. A pixel formed in each of the pixel regions PXR may include all pixel transistors. Alternatively, the transistors on the third substrate 500 may be arranged such that a pair of sub-pixels S_PXR (see FIG. 9) formed in each of the pixel regions PXR share at least one of the logic transistors RX, SX, and DX.

According to one or more embodiments, the first structure S1 and the third structure S3 may be bonded to each other using a copper-to-copper (C2C) bonding method, and the third structure S3 and the second structure S2 may also be bonded to each other using the C2C bonding method. For example, the bonding pads 501, 502, 503, and 504 of the first, second, and third structures S1, S2, S3 may be formed of copper. The first bonding pad 501 of the first structure S1 may be bonded to the third bonding pad 503 of the third structure S3, and the second bonding pad 502 of the second structure S2 may be bonded to the fourth bonding pad 504 of the third structure S3. In one or more embodiments, the fourth bonding pad 504 may be bonded to the second bonding pad 502 through the third substrate 500.

Hereinafter, methods of manufacturing image sensors according to some embodiments will be described.

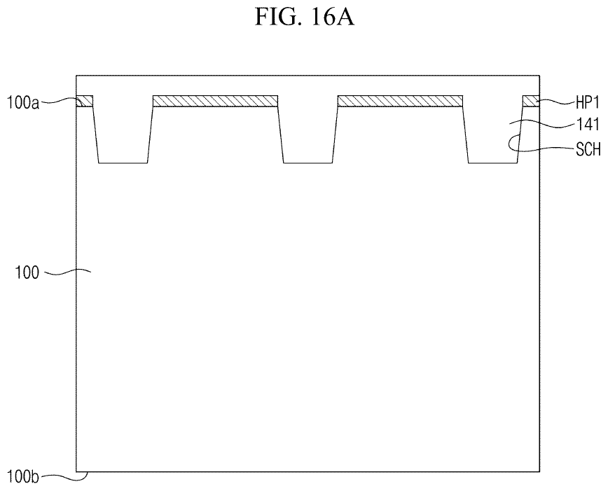

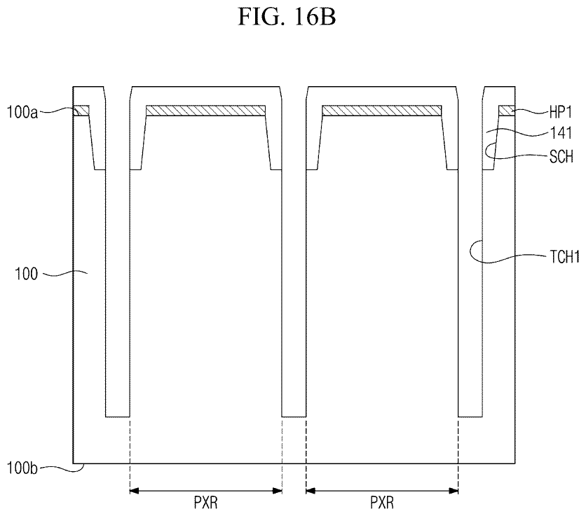

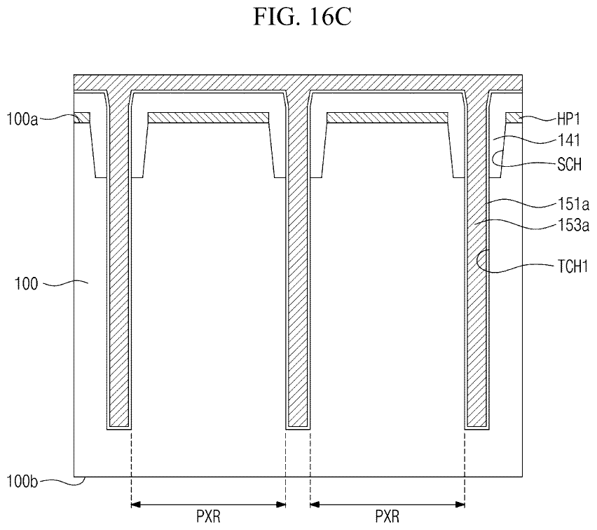

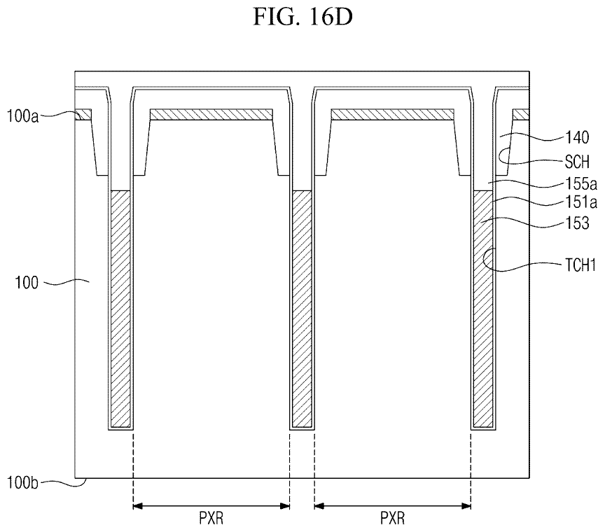

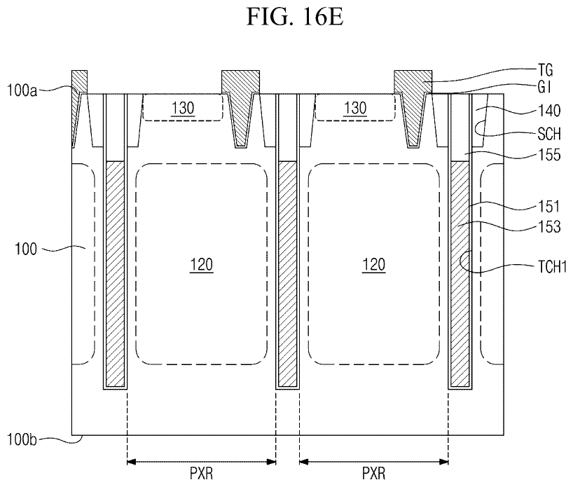

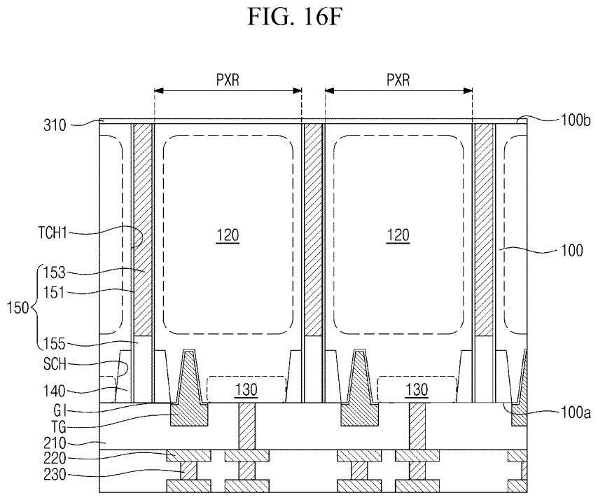

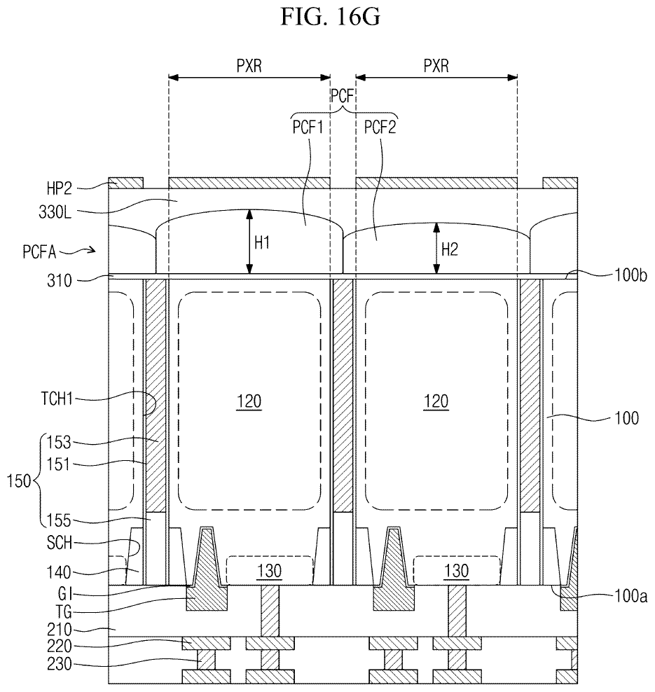

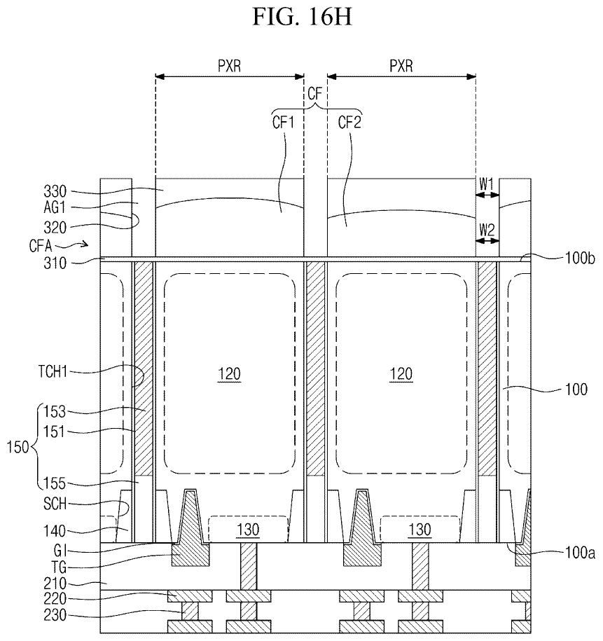

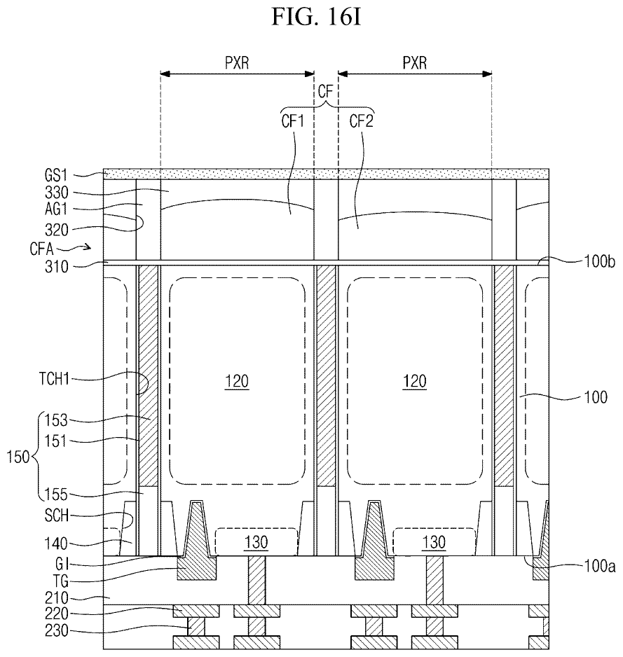

FIGS. 16A to 16I are cross-sectional views illustrating a method of manufacturing an image sensor according to one or more embodiments.

Referring to FIG. 16A, a first hard mask pattern HP1 may be formed on a first surface 100a of a substrate 100 to define a shallow trench SCH. The first hard mask pattern HP1 may be formed of a material having etch selectivity with respect to the substrate 100. For example, the first hard mask pattern HP1 may be formed of at least one of silicon oxide, silicon nitride, or silicon oxynitride. The substrate 100 may be doped with first conductivity-type impurities. The substrate 100 may be etched using the first hard mask pattern HP1 as an etch mask to form the shallow trench SCH.

Then, a shallow isolation layer 141 may be formed on the first surface 100a of the substrate 100 to fill the shallow trench SCH. The shallow isolation layer 141 may cover the first hard mask pattern HP1. The shallow isolation layer 141 may include an insulating material and may be formed using at least one of a deposition process or an oxidation process.

Referring to FIG. 16B, the shallow isolation layer 141 and the substrate 100 may be patterned to form a first deep trench TCH1. The first deep trench TCH1 may extend from the first surface 100a of the substrate 100 toward the second surface 100b of the substrate 100. The first deep trench TCH1 may penetrate through a shallow isolation layer 141 within the shallow trench SCH. The first deep trench TCH1 may define a pixel region PXR.

Referring to FIG. 16C, a first insulating liner layer 151a may be conformally formed on the first surface 100a of the substrate 100 having the first deep trench TCH1. The first insulating liner layer 151a may be formed using at least one of a deposition process or an oxidation process.

Then, a first buried conductive layer 153a may be formed on the first insulating liner layer 151a. The first buried conductive layer 153a may fill the first deep trench TCH1 and may be formed using a deposition process.

Referring to FIG. 16D, the first buried conductive layer 153a may be etched to form a first embedded conductive pattern 153 within the first deep trench TCH1. An upper end of the first embedded conductive pattern 153 may be disposed at a lower level than the first surface 100a of the substrate 100.

Then, a first capping layer 155a may be formed on the substrate 100 having the first embedded conductive pattern 153. The first capping layer 155a may cover the shallow isolation layer 141, the first insulating liner layer 151a, and the first embedded conductive pattern 153. For example, the first capping layer 155a may fill an upper region of the first deep trench TCH1. The first capping layer 155a may be formed using a deposition process.

Referring to FIG. 16E, a planarization process may be performed on the first capping layer 155a (see FIG. 16D) until the first surface 100a of the substrate 100 is exposed. The first hard mask pattern HP1 (see FIG. 16D), the shallow isolation layer 141 (see FIG. 16D), the first insulating liner layer 151a (see FIG. 16D), and the first capping layer 155a (see FIG. 16D) on the first surface 100a may be removed using the planarization process. The planarization process may be performed using at least one of an etch-back process or a chemical mechanical polishing (CMP) process.

A first insulating liner 151, a first capping pattern 155, and a shallow isolation pattern 140 may be formed using the planarization process. The first insulating liner 151, the first capping pattern 155, and the shallow isolation pattern 140 may be exposed on the first surface 100a of the substrate 100.

The shallow isolation pattern 140 may be provided within the shallow trench SCH to define active regions within the pixel regions PXR. Each of the active regions may be a portion of the substrate 100 surrounded by the shallow isolation pattern 140 when viewed in a plan view.

The first capping pattern 155, the first embedded conductive pattern 153, and the first insulating liner 151 may constitute a first deep isolation pattern 150.

Second conductivity-type impurities may be implanted into the substrate 100 to form photoelectric conversion regions 120 within each of the pixel regions PXR. In one or more embodiments, the photoelectric conversion regions 120 may be formed before the formation of the shallow trench SCH or the first deep isolation pattern 150.

A gate trench may be formed within a corresponding active region of each of the pixel regions PXR. A gate insulating layer GI may be formed on inner surfaces of the gate trenches and on the active regions, and a gate conductive layer may be formed on the gate insulating layer GI. The gate conductive layer may fill the gate trenches. The gate conductive layer may be patterned to form transfer gates TG. Gates of logic transistors may also be formed on corresponding active regions of the pixel regions PXR, respectively.

Second conductivity-type impurities may be implanted into the active regions, defined by the shallow isolation pattern 140, to form floating diffusion regions 130. The floating diffusion region 130 may be formed between the photoelectric conversion region 120 and the first surface 100a of the substrate 100. The floating diffusion regions 130 may be provided between the transfer gates TG.

Referring to FIG. 16F, an interlayer dielectric layer 210 may be formed on the first surface 110a of the substrate 100. A contact plug 230 may be formed on the first surface 110a of the substrate 100. The contact plug 230 may be connected to the floating diffusion region 130. The contact plug 230 may be connected to the floating diffusion region 130 through the interlayer dielectric layer 210 to implement the pixel PXL of FIG. 2.

Wirings 220 may be formed on the interlayer dielectric layer 210 to be connected to the contact plug 230. Subsequent processes may be performed on the first surface 100a of the substrate 100. After the subsequent processes on the first surface 100a are completed, the substrate 100 may be flipped.

In one or more embodiments, the contact plug 230, the wirings 220, and the interlayer dielectric layer 210 may be substantially the same as the first contact plug 230a, the first wirings 220a, and the first interlayer dielectric layer 210 illustrated in FIGS. 14 and 15, respectively.

In one or more embodiments, a second structure S2 (see FIG. 14) may be bonded to the substrate 100, as illustrated in FIG. 14. The bonding may be performed through a copper-to-copper bonding process and/or a silicon oxide-to-silicon oxide bonding process. However, the bonding method is not limited thereto and various bonding processes may be performed.

In one or more embodiments, a third structure S3 (see FIG. 15) may be bonded to the substrate 100, as illustrated in FIG. 15. The third structure S3 (see FIG. 15) may be in a pre-bonded state to the second structure S2 (see FIG. 15). The bonding may be performed through a copper-to-copper bonding process and/or a silicon oxide-to-silicon oxide bonding process. In one or more embodiments, the bonding may be performed through a hybrid bonding process in which copper-to-copper bonding and silicon oxide-to-silicon oxide bonding are made. However, the bonding method is not limited thereto and various bonding processes may be performed.

The second surface 100b of the substrate may be polished until the first buried conductive pattern 153 is exposed. The second surface 100b of the substrate 100 may be polished using a chemical mechanical polishing (CMP) process. A hydrogen/deuterium annealing process may be performed to heal defects (for example, dangling bond, or the like) of the polished second surface 100b of the substrate 100.

Then, a transmissive insulating layer 310 may be formed on the second surface 100b of the substrate 100 and the upper surface of the first deep isolation pattern 150. The transmissive insulating layer 310 may be conformally formed and have a thickness varying depending on the pixel region PXR. The transmissive insulating layer 310 may be formed, for example, using a deposition process and/or an oxidation process.

Referring to FIG. 16G, preliminary color filters PCF may be formed on the transmissive insulating layer 310. The preliminary color filters PCF may be two-dimensionally arranged to constitute a preliminary color filter array PCFA. The preliminary color filters PCF may include a first preliminary color filter PCF1 and a second preliminary color filter PCF2 having different colors. A height H1 of the preliminary first color filter CF1 and a height H2 of the second preliminary color filter CF2 may be different from each other.

A planarization layer 330L may be formed on the preliminary color filters PCF. The planarization layer 330L may be formed by applying and curing an organic polymer. In one or more embodiments, the planarization layer 330L may be a liquid-phase material. The planarization layer 330L may be applied in a flat manner on the preliminary color filters PCF. For example, the planarization layer 330L may reduce a height difference between the surfaces of the preliminary color filters PCF and provide a uniform layer for subsequent processes. Then, a heat treatment process may be performed to cross-link the planarization layer 330L. As a result, the planarization layer 330L may be cured.

A second hard mask pattern HP2 may be formed on the planarization layer 330L. For example, the second hard mask pattern HP2 may be provided on a portion of the planarization layer 330L corresponding to the pixel region PXR. The second hard mask pattern HP2 may be formed of a material having etch selectivity with respect to the planarization layer 330L and the preliminary color filters PCF.

Referring to FIG. 16H, a patterning process may be performed to pattern the planarization layer 330L and the preliminary color filters PCF to form the planarization patterns 330 and the color filters CF. The planarization layer 330L and the preliminary color filters PCF may be etched using the second hard mask pattern HP2 as an etch mask. Thus, grid recesses 320 may be formed. The planarization patterns 330 and the color filters CF may be separated by the grid recesses 320. Due to the formation of the grid recesses 320, a first air gap AG1 may be defined in an internal space of the grid recesses 320. An upper width W1 of the first air gap AG1 may be substantially the same as a lower width W2 of the first air gap AG1.

Referring to FIG. 16I, a first glass substrate GS1 may be disposed on the planarization patterns 330. The first glass substrate GS1 may close an upper end of the first air gap AG1.

Returning to FIG. 3B, a deposition process may be performed to form an upper protective layer 360 on the first glass substrate GS1. Then, microlenses ML may be formed on the upper protective layer 360. As a result, the image sensor may be manufactured as illustrated in FIG. 3B.

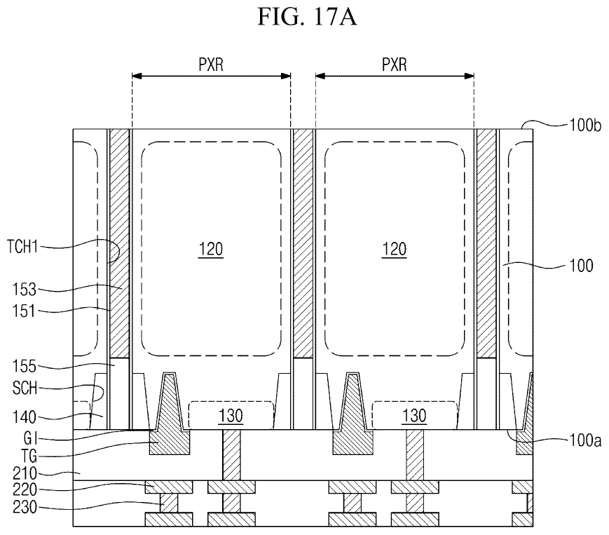

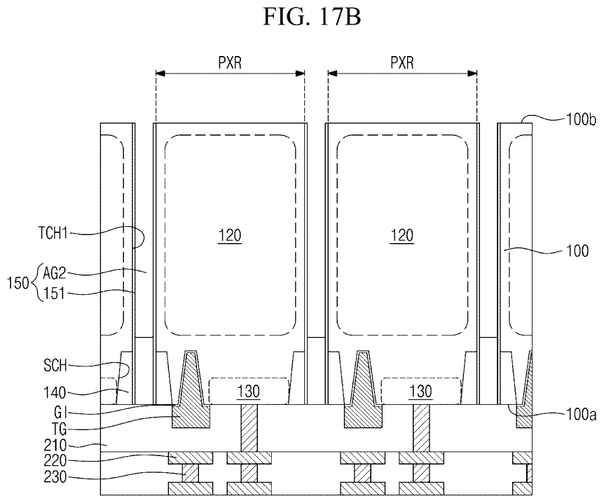

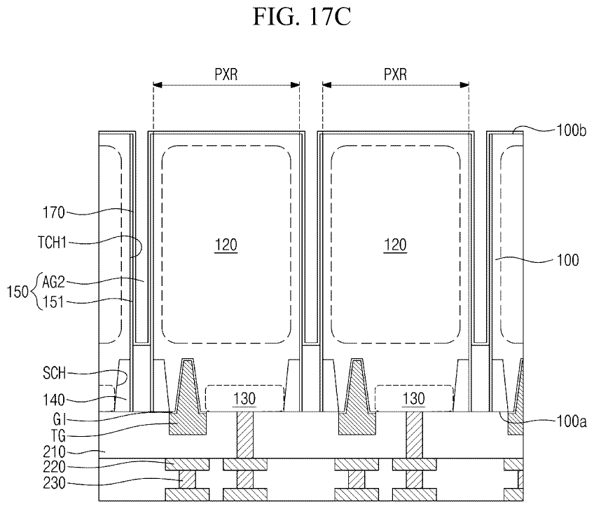

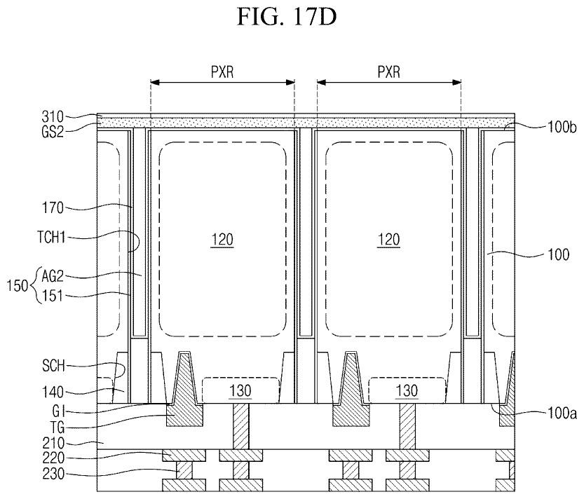

FIGS. 17A to 17D are cross-sectional views illustrating a method of manufacturing an image sensor according to one or more embodiments.

Referring to FIG. 17A, after the process according to FIG. 16E is performed, the second surface 100b of the substrate may be polished until the first buried conductive pattern 153 is exposed. The second surface 100b of the substrate 100 may be polished using a chemical mechanical polishing (CMP) process.

Referring to FIG. 17B, an etching process may be performed to remove the first buried conductive pattern 153. As a result, the first insulating liner 151 may be exposed to air, and a second air gap AG2 may be formed in an internal space of the first deep trench TCH1. For example, the first deep isolation pattern 150 may include the second air gap AG2.

Referring to FIG. 17C, the first insulating layer 170 may be conformally formed on the internal surface of the first deep trench TCH1 and on the second surface 100b of the substrate 100. Thus, the first deep isolation pattern 150 may include a portion of the first insulating layer 170. The first insulating layer 170 may be formed using a deposition process and/or an oxidation process. For example, the first insulating layer 170 may be formed using an atomic layer deposition (ALD) process.

Referring to FIG. 17D, the second glass substrate GS2 may be formed on the first insulating layer 170. The second glass substrate GS2 may close an upper end of the second air gap AG2. A transmissive insulating layer 310 may be formed on the second glass substrate GS2. The transmissive insulating layer 310 may be formed, for example, using a deposition process.

Then, the process operations described with reference to FIGS. 16G to 16I may be performed. As a result, an image sensor may be manufactured as illustrated in FIG. 4.

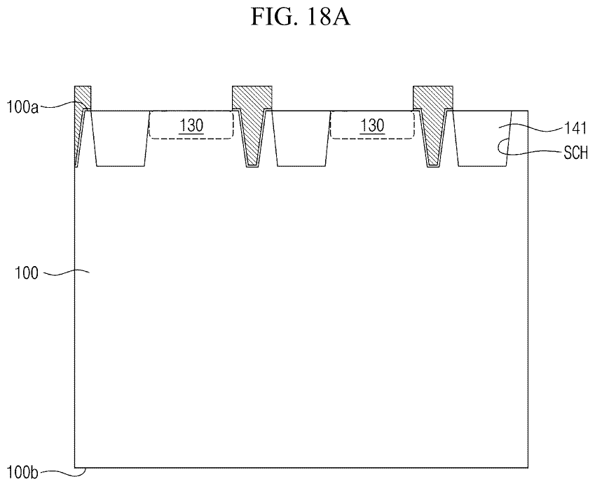

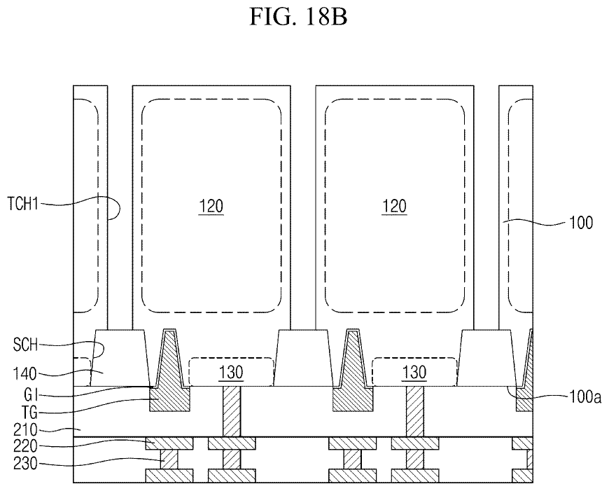

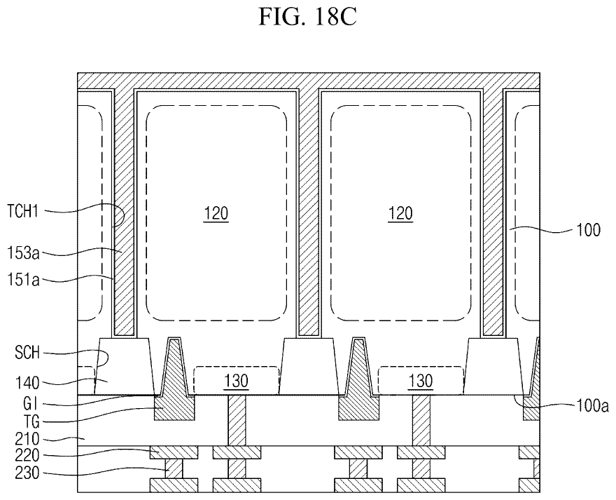

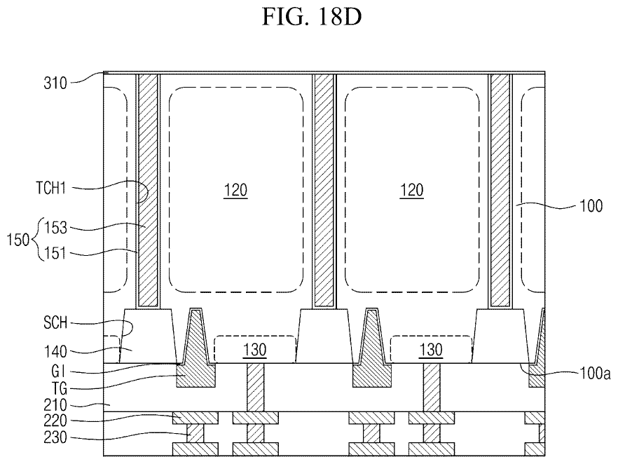

FIGS. 18A to 18D are cross-sectional views illustrating a method of manufacturing an image sensor according to one or more embodiments.

Referring to FIG. 18A, after shallow isolation layers 141 (see FIG. 16A) are formed on the first hard mask pattern HP1 (see FIG. 16A), a chemical mechanical polishing (CMP) process may be performed on the first surface 100a of the substrate 100 to form the shallow isolation pattern 140.

The shallow isolation pattern 140 may be provided within a shallow trench SCH to define active regions. Each of these active regions may be a portion of the substrate 100 surrounded by the shallow isolation pattern 140 when viewed in a plan view.

Referring to FIG. 18B, second conductivity-type impurities may be implanted into the substrate 100 to form the photoelectric conversion regions 120 within each pixel region PXR. In one or more embodiments, the photoelectric conversion regions 120 may be formed before the formation of the shallow trench SCH or before the formation of the first deep isolation pattern 150.

A gate trench may be formed within each corresponding active region of the pixel regions PXR. A gate insulating layer GI may be formed on the inner surfaces of the gate trenches and on the active regions, and a gate conductive layer may be formed on the gate insulating layer GI. The gate conductive layer may fill the gate trenches. The gate conductive layer may be patterned to form transfer gates TG. Gates of logic transistors may also be formed on each corresponding active region of the pixel regions PXR.

In addition, the second conductivity-type impurities may be implanted between the transfer gates TG to form floating diffusion regions 130. Then, an interlayer dielectric layer 210, a contact plug 230, and wirings 220 may be formed on the first surface 110a of the substrate 100. Subsequent processes may be performed on the first surface 100a of the substrate 100. After the subsequent processes performed on the first surface 100a are completed, the substrate 100 may be flipped.

After the substrate 100 is flipped, a patterning process may be performed on the second surface 100b of the substrate 100 to form the first trench TCH1 within the substrate. The first trench TCH1 may be recessed downward from the second surface 100b of the substrate 100 toward the first surface 100a of the substrate 100. In one or more embodiments, the first trench TCH1 may be connected to the shallow trench SCH.

Referring to FIG. 18C, a first insulating liner layer 151a and a first buried conductive layer 153a may be sequentially formed in the first trench TCH1 and on the second surface 100b of the substrate 100. The first insulating liner layer 151a and the first buried conductive layer 153a may be formed, for example, using a deposition process and/or an oxidation process.

Referring to FIG. 18D, a planarization process may be performed to polish the second surface 100b of the substrate, the first insulating liner layer 151a, and the first buried conductive layer 153a. Accordingly, the first insulating liner 151 and the first buried conductive pattern 153 may be formed. The planarization process may be performed through a chemical mechanical polishing (CMP) process.

A deposition process and/or an oxidation process may be performed to form a transmissive insulating layer 310 on the upper surface of the first deep isolation pattern 150 and the second surface 100b of the substrate.

Then, the process operations described with reference to FIGS. 16G to 16I may be performed. As a result, an image sensor may be manufactured as illustrated in FIG. 6.

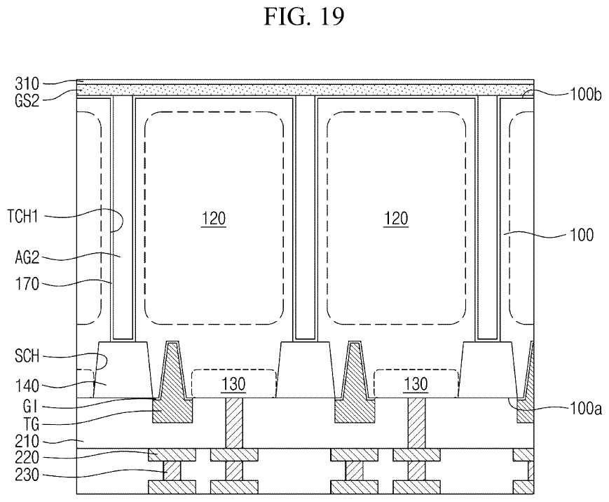

FIG. 19 is a cross-sectional view illustrating a method of manufacturing an image sensor according to one or more embodiments.

Referring to FIG. 19, after the first trench TCH1 is formed as illustrated in FIG. 18B, the first insulating layer 170 may be conformally formed on the inner surface of the first trench TCH1 and on the second surface 100b of the substrate 100. The first insulating layer 170 may be formed, for example, using a deposition process and/or an oxidation process. For example, the first insulating layer 170 may be formed using an atomic layer deposition (ALD) process.

The first insulating layer 170 may be conformally formed to provide air to the internal space of the first trench TCH1. Accordingly, the second air gap AG2 may be formed in the internal space of the first trench TCH1.

Then, the second glass substrate GS2 may be provided on the second surface 100b of the substrate 100 and the first insulating layer 170. The second glass substrate GS2 may close an upper end of the second air gap AG2. For example, the second glass substrate GS2 may seal the second air gap AG2. The first insulating layer 170 may function as an adhesive layer to facilitate adhesion of the second glass substrate GS2 to the second surface 100b of the substrate 100.

A transmissive insulating layer 310 may be formed on the second glass substrate GS2. The transmissive insulating layer 310 may be formed, for example, using a deposition process and/or an oxidation process.

Then, the process operations described with reference to FIGS. 16G to 16I may be performed. As a result, an image sensor may be manufactured as illustrated in FIG. 7.

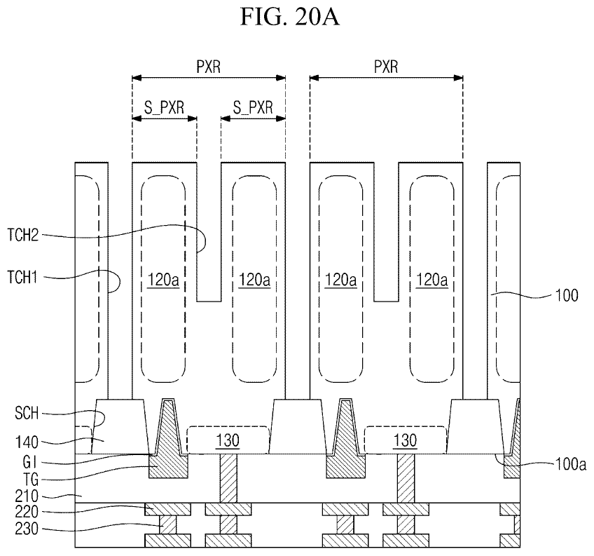

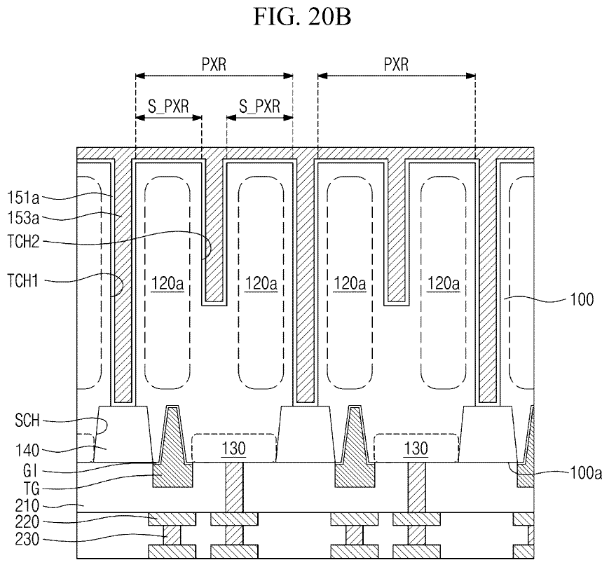

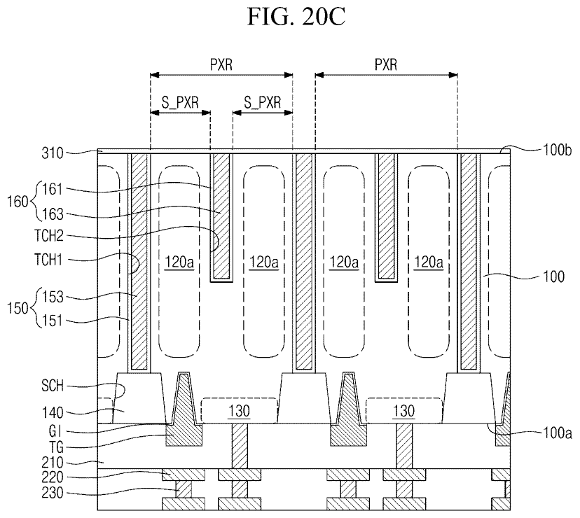

FIGS. 20A to 20C are cross-sectional views illustrating a method of manufacturing an image sensor according to one or more embodiments.

Referring to FIG. 20A, after the first trench TCH1 is formed, a patterning process may be performed again on the second surface 100b of the substrate 100 to form a second trench TCH2, as illustrated in FIG. 18B. The second trench TCH2 may be formed between adjacent first trenches TCH1. The formation of the second trench TCH2 may lead to the definition of a pair of sub-pixel regions S_PXR within a single pixel region PXR. The second trench TCH2 may separate the pair of sub-pixel regions S_PXR.

In addition, second conductivity-type impurities may be implanted into the substrate 100 to form a photoelectric conversion region 120a in each of the sub-pixel regions S_PXR. In one or more embodiments, the photoelectric conversion region 120a may be formed before the formation of the shallow trench SCH or before the formation of the first and second trenches TCH1 and TCH2.

Referring to FIG. 20B, a first insulating liner layer 151a and a first buried conductive layer 153a may be formed sequentially on the inner surfaces of the first and second trenches TCH1 and TCH2 and the second surface 100b of the substrate 100. The first insulating liner layer 151a and the first buried conductive layer 153a may fill both the first and second trenches TCH1 and TCH2. The first insulating liner layer 151a may be formed using an oxidation process and/or a deposition process. The first buried conductive layer 153a may be formed using a deposition process.

Referring to FIG. 20C, a planarization process may be performed to polish the second surface 100b of the substrate, the first insulating liner layer 151a, and the first buried conductive layer 153a. Thus, a first insulating liner 151, a first buried conductive pattern 153, a second insulating liner 161, and a second buried conductive pattern 163 may be formed. Each of the first deep isolation pattern 150 and the second deep isolation pattern 160 may be defined by the planarization process. The planarization process may be performed through a chemical mechanical polishing (CMP) process.

A deposition process and/or an oxidation process may be performed to form a transmissive insulating layer 310 on the upper surfaces of the first and second deep isolation patterns 150 and 160 and on the second surface 100b of the substrate 100.

Then, the process operations described with reference to FIGS. 16G to 16I may be performed. As a result, an image sensor may be manufactured as illustrated in FIG. 9.

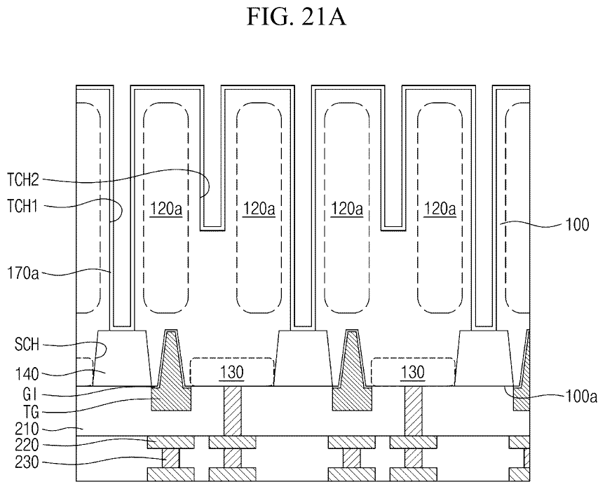

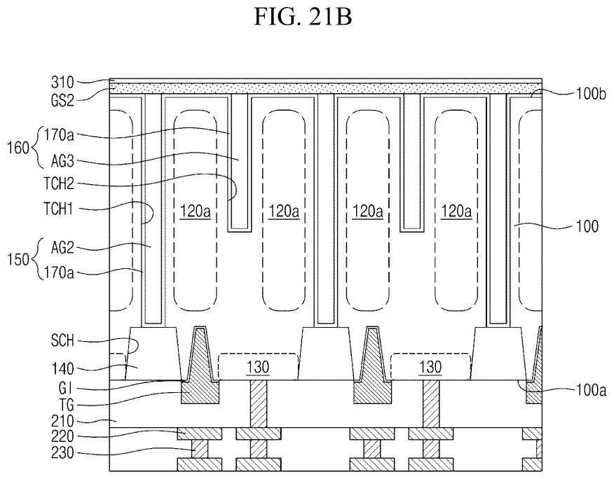

FIGS. 21A and 21B are cross-sectional views illustrating a method of manufacturing an image sensor according to one or more embodiments.

Referring to FIG. 21A, after the second trenches TCH2 are formed, a first insulating layer 170a may be conformally formed on the inner surfaces of the first trench TCH1, the second trenches TCH2, and the second surface 100b of the substrate 100, as illustrated in FIG. 20A. The first insulating layer 170 may be formed, for example, using a deposition process and/or an oxidation process. The first insulating layer 170 may be formed using an atomic layer deposition (ALD) process.

The first insulating layer 170 may be conformally formed to provide air to internal spaces of the first and second trenches TCH1 and TCH2. Accordingly, a second air gap AG2 may be formed in the internal space of the first trench TCH1, and a third air gap AG3 may be formed in the internal space of the second trench TCH2.

Referring to FIG. 21B, a second glass substrate GS2 may be provided on the second surface 100b of the substrate 100 and on the first insulating layer 170. The second glass substrate GS2 may close upper ends of the second air gap AG2 and the third air gap AG3. For example, the second glass substrate GS2 may seal the second and third air gaps AG2 and AG3. The first insulating layer 170 may function as an adhesive layer to facilitate adhesion of the second glass substrate GS2 to the second surface 100b of the substrate 100.

A portion of the first insulating layer 170a provided on the inner surface of the first trench TCH1 and the second air gap AG2 may form the first deep isolation pattern 150, and the portion of the first insulating layer 170a provided on the inner surface of the second trench TCH2 and the third air gap AG3 may constitute the second deep isolation pattern 160.

A transmissive insulating layer 310 may be formed on the second glass substrate GS2. The transmissive insulating layer 310 may be formed, for example, using a deposition process and/or an oxidation process.

Then, the process operations described with reference to FIGS. 16G to 16I may be performed. As a result, an image sensor may be manufactured as illustrated in FIG. 10.

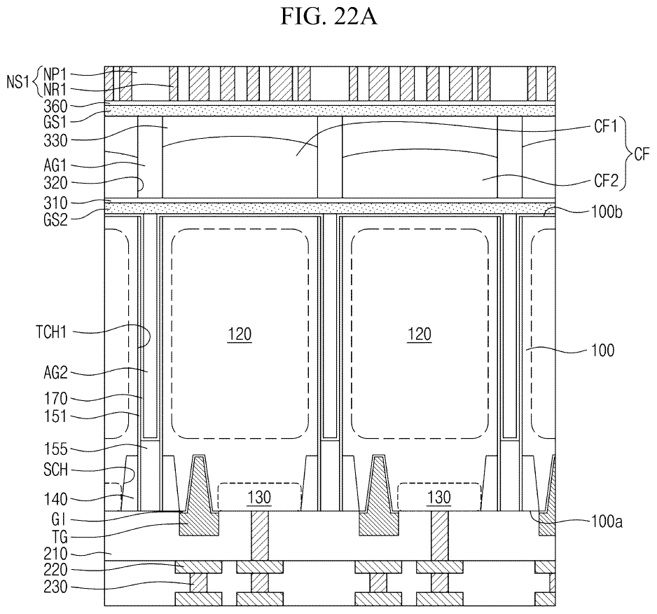

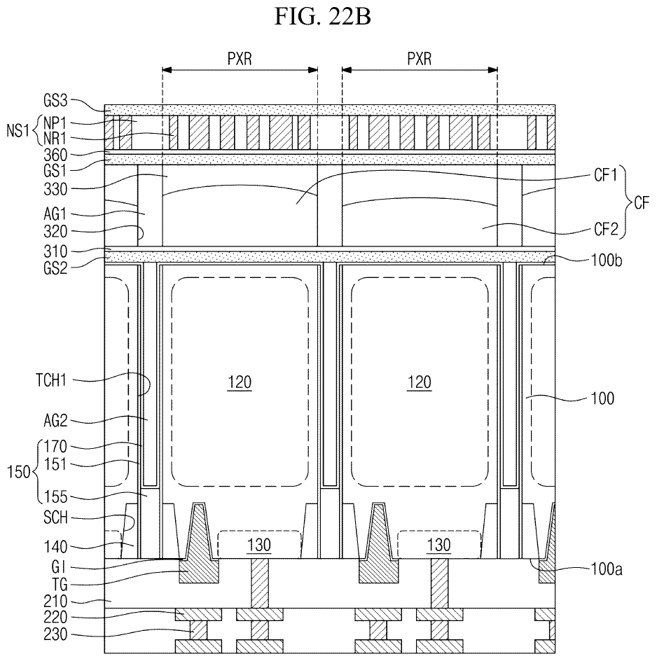

FIGS. 22A and 22B are cross-sectional views illustrating a method of manufacturing an image sensor according to one or more embodiments.

Referring to FIG. 22A, after the first glass substrate GS1 is formed through the process operations described with reference to FIGS. 16G to 16I, an upper protective layer 360 may be formed on the first glass substrate GS1. The upper protective layer 360 may be formed using, for example, a deposition process.

Then, a first initial nanostructure layer may be formed on the upper protective layer 360. The first initial nanostructure layer may be formed of a material having a relatively low refractive index. The first initial nanostructure layer may be formed using, for example, a deposition process and/or an oxidation process.

The first initial nanostructure layer may be patterned using a photolithography process and an etching process. Thus, a first nanorefractive pattern NR1 may be formed. The first nanorefractive pattern NR1 may include a plurality of openings using patterning, and a high refractive index material may be deposited within the plurality of openings.

Then, a planarization process may be performed on an upper surface of the first nanorefractive pattern NR1. The planarization process may be, for example, a polishing process using chemical mechanical polishing. Thus, first nano posts NP1 may be formed in the openings of the first nanorefractive pattern NR1. The first nano posts NP1 and the first nanorefractive pattern NR1 may constitute a first nanostructure layer NS1.

Referring to FIG. 22B, a third glass substrate GS3 may be disposed on an upper surface of the first nanostructure layer NS1.

Returning to FIGS. 5, 8, and 11, a second initial nanostructure layer may be formed on the third glass substrate GS3, and the second initial nanostructure layer may be patterned to form a second nanorefractive pattern NR2. The second nanorefractive pattern NR2 may include a plurality of openings using patterning, and a high refractive index material may be deposited within the plurality of openings.

Then, a planarization process may be performed on an upper surface of the second nanorefractive pattern NR2. The planarization process may be, for example, a polishing process using chemical mechanical polishing. Thus, second nano posts NP2 may be formed in the openings of the second nanorefractive pattern NR2. The second nano posts NP2 and the second nanorefractive pattern NR2 may constitute the second nanostructure layer NS2. As a result, image sensors may be manufactured as illustrated in FIGS. 5, 8, and 11, respectively.

As set forth above, according to one or more embodiments, an image sensor may reduce crosstalk.

In addition, according to one or more embodiments, an image sensor may improve photoelectric conversion efficiency by significantly reducing optical loss.

While various embodiments have been shown and described above, it will be apparent to those skilled in the art that modifications and variations could be made without departing from the scope of the present inventive concept as defined by the appended claims.

What is claimed is:

1. An image sensor comprising:
a substrate having a first surface and a second surface opposing the first surface;
a transmissive insulating layer provided on the second surface of the substrate;
a plurality of color filters provided on the transmissive insulating layer;
a plurality of planarization patterns provided on the plurality of color filters;
a first air gap provided within a recess between the plurality of color filters and between the plurality of planarization patterns; and
a first glass substrate provided on the plurality of planarization patterns and the first air gap and closing an upper end of the first air gap.

2. The image sensor of claim 1, wherein:
the plurality of color filters include a first color filter and a second color filter having different heights relative to the second surface of the substrate; and
the first color filter and the second color filter are configured to transmit light of different wavelengths.

3. The image sensor of claim 2, wherein:
the plurality of planarization patterns include a first planarization pattern on the first color filter and a second planarization pattern on the second color filter; and
an upper surface of the first planarization pattern is disposed at substantially the same level as an upper surface of the second planarization pattern.

4. The image sensor of claim 1, further comprising:
a first isolation pattern provided in a first deep trench formed in the substrate to define a plurality of pixel regions.

5. The image sensor of claim 4, wherein:
the first isolation pattern comprises a second air gap; and
the image sensor further comprises a second glass substrate provided between the substrate and the transmissive insulating layer to close an upper end of the second air gap.

6. The image sensor of claim 5, further comprising:
a first insulating layer provided on the second surface of the substrate and an inner surface of the first deep trench,
wherein the second glass substrate is disposed on the first insulating layer.

7. The image sensor of claim 6,
wherein the first isolation pattern further comprises a first insulating liner provided between the first insulating layer and the substrate.

8. The image sensor of claim 5, further comprising:
a second isolation pattern provided in each of the plurality of pixel regions to define a pair of sub-pixel regions,
wherein a bottom surface of the second isolation pattern is disposed at a level between the first surface and the second surface of the substrate.

9. The image sensor of claim 8, wherein the second isolation pattern comprises a third air gap.

10. The image sensor of claim 4, further comprising:
a plurality of meta-microlenses covering the plurality of pixel regions,
wherein each of the plurality of meta-microlenses comprises:
a first nanostructure layer on the first glass substrate;
a second nanostructure layer on the first nanostructure layer; and
a meta glass substrate provided between the first nanostructure layer and the second nanostructure layer.

11. The image sensor of claim 1, further comprising:
an insulating layer conformally provided on an inner surface of the recess and upper surfaces of the plurality of planarization patterns,
wherein the first glass substrate is disposed on the insulating layer.

12. The image sensor of claim 11, wherein:
refractive indices of the plurality of color filters and a refractive index of the insulating layer are each greater than a refractive index of the first air gap.

13. The image sensor of claim 1, further comprising:
an adhesive film provided between the first glass substrate and the plurality of planarization patterns.

14. The image sensor of claim 1,
wherein an upper width of the first air gap is substantially the same as a lower width of the first air gap.

15. The image sensor of claim 1,
wherein the plurality of planarization patterns comprise silicon oxide (SiO₂), titanium oxide (TiO₂), aluminum oxide (Al₂O₃), tantalum oxide (Ta₂O₅), hafnium oxide (HfO₂), or combinations thereof.

16. An image sensor comprising:
a substrate having a first surface and a second surface opposing the first surface;
a transmissive insulating layer provided on the second surface of the substrate;
a plurality of color filters provided on the transmissive insulating layer and comprising a first color filter and a second color filter having different heights relative to the second surface of the substrate;
a plurality of planarization patterns provided on the plurality of color filters;
a first air gap provided within a recess between the plurality of color filters and between the plurality of planarization patterns;
a first glass substrate provided on the plurality of planarization patterns and the first air gap to close an upper end of the first air gap;
a first isolation pattern provided in the substrate to define a plurality of pixel regions and comprising a second air gap; and
a second glass substrate provided between the substrate and the transmissive insulating layer to close an upper end of the second air gap,
wherein the first color filter and the second color filter are configured to transmit light of different wavelengths.

17. The image sensor of claim 16, further comprising:
a second isolation pattern provided in each of the plurality of pixel regions to define a pair of sub-pixel regions,
wherein:
a bottom surface of the second isolation pattern is disposed at a higher level than a bottom surface of the first isolation pattern;
the second isolation pattern comprises a third air gap; and
the second glass substrate closes an upper end of the third air gap.

18. An image sensor comprising:
a substrate having a first surface and a second surface opposing the first surface;
a transmissive insulating layer provided on the second surface of the substrate;
a plurality of color filters provided on the transmissive insulating layer and comprising a first color filter and a second color filter having different heights relative to the second surface of the substrate;
a plurality of planarization patterns provided on the plurality of color filters;
a first air gap provided within a recess between the plurality of color filters and between the plurality of planarization patterns;
a first glass substrate provided on the plurality of planarization patterns and the first air gap to close an upper end of the first air gap;
a first isolation pattern provided in the substrate to define a plurality of pixel regions and comprising a second air gap;
a second glass substrate provided between the substrate and the transmissive insulating layer to close an upper end of the second air gap; and
a plurality of meta-microlenses covering the plurality of pixel regions and each comprising a first nanostructure layer on the first glass substrate and a second nanostructure layer on the first nanostructure layer,
wherein:
the first color filter and the second color filter are configured to transmit light of different wavelengths; and
each of the plurality of meta-microlenses comprises a third glass substrate provided between the first nanostructure layer and the second nanostructure layer.

19. The image sensor of claim 18, wherein:
the first nanostructure layer comprises:
a plurality of first nanoposts disposed on a first surface of the third glass substrate, extending in a vertical direction perpendicular to the third glass substrate, and horizontally spaced apart from each other; and
a first nanorefractive pattern provided between the plurality of first nanoposts and having a refractive index different from a refractive index of the plurality of first nanoposts, and
the second nanostructure layer comprises:
a plurality of second nanoposts disposed on a second surface opposing the first surface the third glass substrate, extending in the vertical direction, and horizontally spaced apart from each other; and
a second nanorefractive pattern provided between the plurality of second nanoposts and having a refractive index different from a refractive index of the plurality of second nanoposts.

20. The image sensor of claim 18, wherein:
the plurality of planarization patterns include a first planarization pattern on the first color filter and a second planarization pattern on the second color filter; and
an upper surface of the first planarization pattern is disposed at substantially the same level as an upper surface of the second planarization pattern.
